(19) United States
(12) Patent Application Publication
(10) Pub. No.: US 2024/0371774 A1
(43) Pub. Date: Nov. 7, 2024

(54) PACKAGE MODULE INCLUDING A RECESSED UPPER SURFACE AND METHODS OF FORMING THE PACKAGE MODULE

(71) Applicant: Taiwan Semiconductor Manufacturing Company Limited, Hsinchu (TW)

(72) Inventors: Kuan-Lin Ho, Hsinchu City (TW); Chien-Hsun Lee, Hsinchu (TW); Chi-Yang Yu, Zhongli City (TW); Jung Wei Cheng, Hsinchu City (TW)

(21) Appl. No.: 18/309,874

(22) Filed: May 1, 2023

(51) Int. Cl. H01L 23/538; H01L 21/48; H01L 21/56; H01L 23/31; H01L 23/36; H01L 25/00; H01L 25/065

(52) U.S. Cl. CPC H01L 23/5381; H01L 21/4857; H01L 21/563; H01L 23/3157; H01L 23/36; H01L 23/5383; H01L 25/0655; H01L 25/50

(57) ABSTRACT

A package module includes an interposer, a plurality of semiconductor dies on the interposer and including a semiconductor die upper surface, an upper molding material layer on the plurality of semiconductor dies and including a recessed upper surface that is recessed from the semiconductor die upper surface, and a backside metal layer on the recessed upper surface of the upper molding material layer.

### BACKGROUND

Typical package modules may include a plurality of semiconductor dies and an upper molding material layer around the semiconductor dies. An upper surface of the upper molding material layer may be grinded (e.g., chemical mechanical polishing (CMP)) down so that the upper surface of the upper molding material layer is coplanar with an upper surface of the semiconductor dies. Package structures including these package modules may then be formed without a lid (e.g., a lidless package structure) to facilitate heat dissipation away from the package module.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package module according to one or more embodiments.

FIG. 1B is a plan view (e.g., top-down view) of the package module according to one or more embodiments.

FIG. 1C is a vertical cross-sectional view of a detailed portion of the package module according to one or more embodiments.

FIG. 2A is a vertical cross-sectional view of an intermediate structure including a portion of the interposer RDL portion (e.g., organic interposer) formed on a first carrier substrate (e.g., carrier wafer) according to an embodiment of the present invention.

FIG. 2B is a vertical cross-sectional view of an intermediate structure including the LSI dies according to one or more embodiments.

FIG. 2C is a vertical cross-sectional view of an intermediate structure including the molding material layer according to one or more embodiments.

FIG. 2D is a vertical cross-sectional view of an intermediate structure including the first semiconductor die, second semiconductor die, fourth semiconductor die and fifth semiconductor die on the interposer molded portion according to one or more embodiments.

FIG. 2E is a vertical cross-sectional view of an intermediate structure including the package module underfill layer according to one or more embodiments.

FIG. 2F illustrates a vertical cross-sectional view of an intermediate structure including the upper molding material layer according to one or more embodiments.

FIG. 2G illustrates a vertical cross-sectional view of an intermediate structure including the plurality of C4 bumps and the IPDs, according to one or more embodiments.

FIG. 2H is a vertical cross-sectional view of an intermediate structure including the recessed upper surface according to one or more embodiments.

FIG. 3 is a flow chart illustrating a method of forming the package module according to one or more embodiments.

FIG. 4 is a vertical cross-sectional view of the package module having a first alternative design according to one or more embodiments.

FIG. 5A is a plan view of a first alternative design (e.g., pattern) of the backside metal layer according to one or more embodiments.

FIG. 5B is a plan view of a second alternative design of the backside metal layer according to one or more embodiments.

FIG. 6 is a vertical cross-sectional view of a package structure according to one or more embodiments.

FIG. 7 is a vertical cross-sectional view of the package structure having a first alternative design according to one or more embodiments.

FIG. 8 is a vertical cross-sectional view of the package structure having a second alternative design according to one or more embodiments

FIG. 9 is a vertical cross-sectional view of the package structure having a third alternative design according to one or more embodiments.

FIG. 10A is a plan view of the adhesive layer having a first design pattern according to one or more embodiments.

FIG. 10B is a plan view of the adhesive layer having a second design pattern according to one or more embodiments.

FIG. 11A is a vertical cross-sectional view of a package structure having a fourth alternative design according to one or more embodiments.

FIG. 11B is a plan view (i.e., top-down view) of the package structure having the fourth alternative design according to one or more embodiments.

FIG. 12 is a vertical cross-sectional view of a package structure having a fifth alternative design according to one or more embodiments.

FIG. 13 is a vertical cross-sectional view of a package structure having a sixth alternative design according to one or more embodiments.

FIG. 14 is a vertical cross-sectional view of a package structure having a seventh alternative design according to one or more embodiments.

FIG. 15 is a plan view of a third alternative design of the backside metal layer according to one or more embodiments.

FIG. 16 is a plan view of the adhesive layer having a third design pattern according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Package structures (e.g., lidless package structures) that include the typical package modules may experience warpage control issues. The high temperatures that the package structures may be exposed to in conjunction with materials having varying coefficients of thermal expansion (CTE) may result in warpage and stress placed upon the components of the package structure. In particular, the package structures may experience board level process yield loss and reliability concerns due to high warpage. Structures such as stiffener rings and a lid may mitigate against warpage.

The package structures may also experience thermal dissipation issues and, therefore, require a thermal interface material (TIM) having a high thermal conductivity (high-k). These problems may be especially problematic for package structures directed to high performance computing (HPC) products. As noted above, structures such as stiffener rings and lids may mitigate against warpage. However, the use of structures such as a lid may impede heat dissipation. Thus, solutions to mitigate against warpage and/or improve heat dissipation such that the use of a lid that may improve warpage characteristics do not impact heat dissipation are desired.

One or more embodiments of the present disclosure may include a package module that may address the warpage control issues and thermal dissipation issues commonly experienced by typical package structures (e.g., chip on wafer on substrate (CoWoS®) structures). In at least one embodiment, the package module may include a molding-based interposer including a local silicon interconnect (LSI) chip for connecting semiconductor dies in the package structure.

In one or more embodiments, the package module may include an interposer including an interposer redistribution layer (RDL) portion and an interposer molded portion on the interposer RDL portion. The package module may further include a plurality of semiconductor dies on the interposer. The package module may further include an upper molding material layer around the semiconductor dies. In contrast to the typical package structures in which the upper surface of the upper molding material layer (e.g., between the semiconductor dies) is coplanar with the upper surface of the semiconductor dies, in the present disclosure the upper surface of the upper molding material layer may not be coplanar with the upper surface of the semiconductor dies.

In one or more embodiments, the package modules may also include one or more dummy dies mounted on the interposer. The upper molding material layer may be formed around the dummy dies. The dummy dies may help mechanical stability to the package module.

In one or more embodiments, the upper molding material layer may include a recessed upper surface that is recessed from an upper surface of the plurality of semiconductor dies. In particular, a height of the upper surface of the upper molding material layer may be less than a height of the upper surface of the semiconductor dies. In at least one embodiment, the recessed upper surface is formed between the semiconductor dies. The package module may also include a backside metal (BSM) layer on the recessed upper surface of the upper molding material layer.

In contrast to other package modules, various embodiment package modules of the present disclosure may include a recessed upper surface of the upper molding material layer (e.g., epoxy molding compound (EMC)). Various embodiment package modules may also include the BSM layer on the semiconductor dies and on the recessed upper surface of the upper molding material layer between the semiconductor dies. In at least one embodiment, the BSM layer may be formed on the recessed upper surface of the upper molding material layer outside the semiconductor dies. The recessed upper surface may result in an increased surface area of a thermal dissipation material such as the BSM layer such that the thermal dissipation characteristics are improved such that the use of a lid is permitted to help control warpage. In this manner the features of the embodiments disclosed herein may allow the package module to avoid warpage control issues and thermal dissipation issues.

Thus, the features of various embodiments disclosed herein (e.g., the recessed upper surface of the upper molding material layer combined with the BSM layer on the semiconductor dies and the recessed upper surface) may improve the thermal dissipation characteristics of the package module. This improved thermal dissipation may allow the package module to further incorporate a lid structure to improve warpage characteristics despite the decrease in heat dissipation due to the use of the lid.

One or more embodiments may include a package structure including the package module. In such embodiments, a TIM layer may be located on the BSM layer on the recessed upper surface of the upper molding material layer. A package lid may be located on the upper molding material layer over the TIM layer. The package lid may be attached to the package module by an adhesive wall around an area of the semiconductor dies, and an adhesive foot around an edge of the package structure. In particular, the package lid may be attached to the BSM layer and/or the upper surface (e.g., recessed upper surface) of the upper molding material layer. The BSM layer may have different patterns in a plan view (e.g., top-down view). The adhesive wall and the adhesive foot may also have different patterns in the plan view.

The package structure may include several features that are different from the typical package structure. In such embodiments, the package structure may include a package lid, TIM layer, adhesive and BSM layer. The package structure may have different configurations with different BSM layer patterns and/or adhesive patterns. The package structure may also include a recessed upper surface of the upper molding material layer (e.g., epoxy molding compound (EMC)). The features of the package structure may help to reduce package warpage, and may provide a current tool for an on substrate (oS) loop.

The package structure may have a plurality of different configurations. In at least one embodiment, the package structure may have different configurations that vary according to a selected method of manufacturing. In at least one embodiment, the package structure may have a first configuration in embodiments in which the package substrate is attached to an interposer wafer and then singulated as a complete unit. In at least one embodiment, the package structure may have a second configuration different than the first configuration in embodiments in which the package module is singulated and then attached to the package substrate.

The various embodiments package structures may provide several advantages over a other package structures. In particular, the various embodiment package structures may provide better warpage control. For example, the various embodiment package structures may have improved thermal dissipation characteristics that would allow for the use of a package lid in the package structure. As noted above, while a package lid may improve warpage control, its use may be detrimental to thermal dissipation. Thus, the various embodiment package structures may also provide good thermal dissipation. For example, by recessing the upper surface of the upper molding material layer, the overall upper surface area of the upper molding material layer may be increased due the recesses and sidewall surfaces that may be created in subsequent deposited BSM layers over the semiconductor dies and recessed surfaces. In addition, the use of thermally conductive BSM layers may also improve the thermal dissipation characteristics of the embodiment package structures.

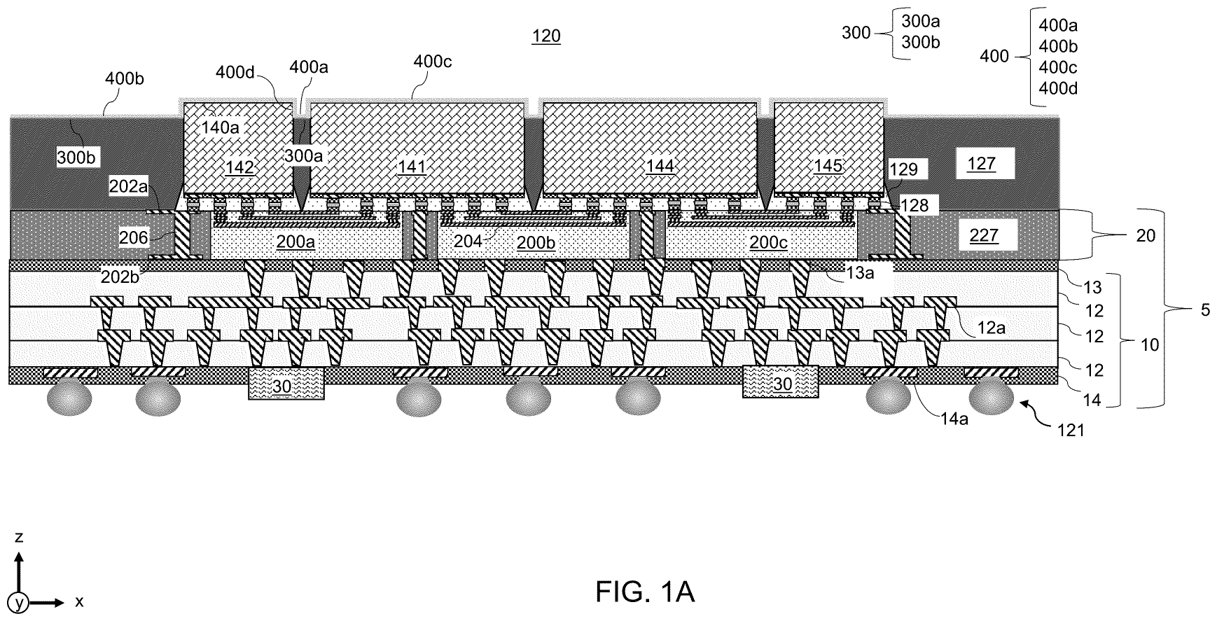

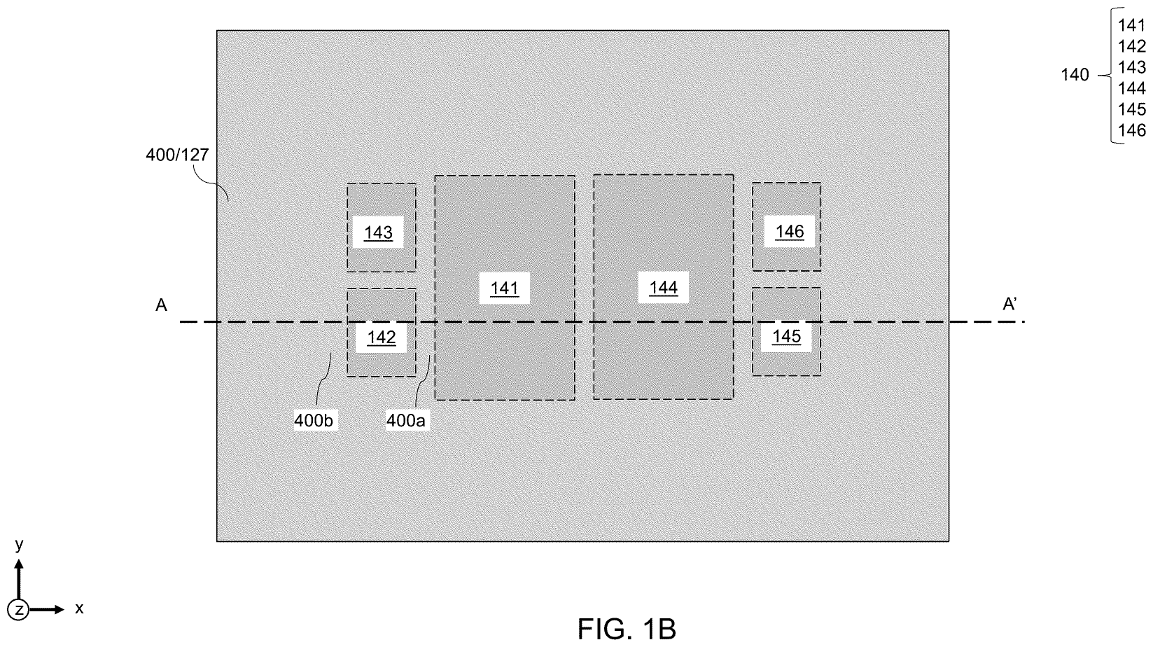

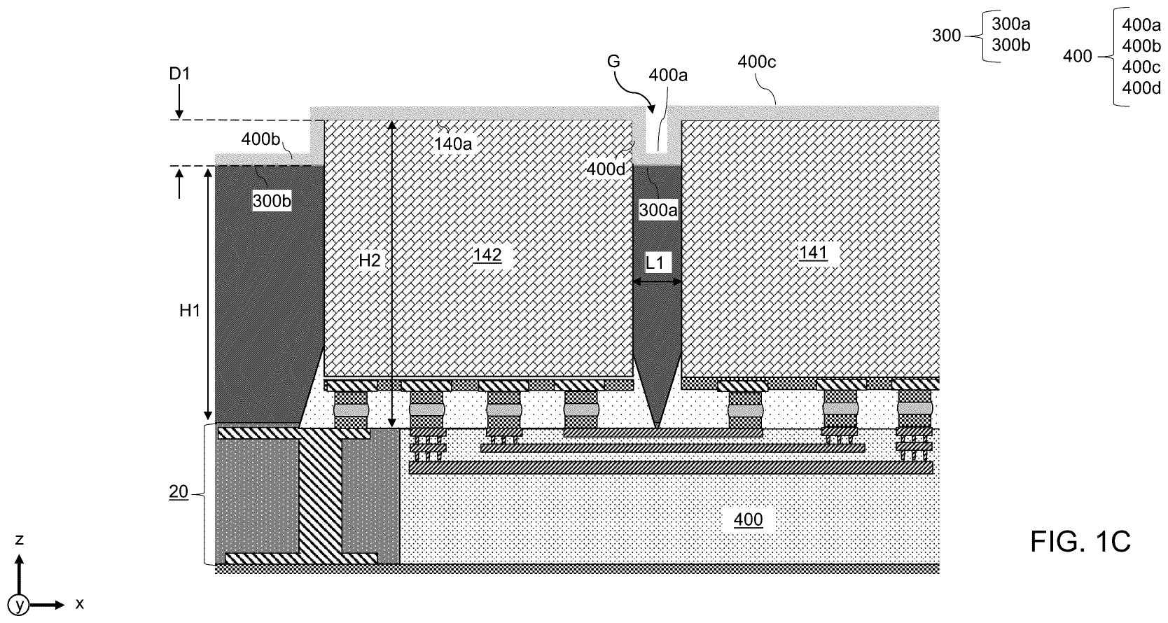

FIG. 1A is a vertical cross-sectional view of a package module 120 according to one or more embodiments. FIG. 1B is a plan view (e.g., top-down view) of the package module 120 according to one or more embodiments. The vertical cross-sectional view in FIG. 1A is along the line A-A′ in FIG. 1B. The package module 120 may include a first set of semiconductor dies including a first semiconductor die 141, second semiconductor die 142 and third semiconductor die 143 (see FIG. 1B), on an interposer 5. The package module 120 may also include a second set of semiconductor dies including a fourth semiconductor die 144, fifth semiconductor die 145 and sixth semiconductor die 146 (see FIG. 1B), on the interposer 5. The first semiconductor die 141, second semiconductor die 142, third semiconductor die 143, fourth semiconductor die 144, fifth semiconductor die 145 and sixth semiconductor die 146 may be referred to collectively as the semiconductor dies 140 (see FIG. 1B).

Although the package module 120 is illustrated as including a particular number of semiconductor dies having a particular arrangement, the number of semiconductor dies and the arrangement of the semiconductor dies is not limited to any particular number and arrangement. In particular, the package module 120 may include any number and arrangement of semiconductor dies and any number and arrangement of semiconductor die sets.

The interposer 5 is not necessarily limited to any particular materials or configuration. The interposer 5 may include, for example, organic material (e.g., dielectric polymer), inorganic material (e.g., silicon), glass substrate, etc. In at least one embodiment, as illustrated in FIG. 1A, the interposer 5 may include an interposer RDL portion 10 and an interposer molded portion 20 on the interposer RDL portion 10.

In at least one embodiment, the interposer RDL portion 10 may include a plurality of polymer layers 12 and a plurality of redistribution layers 12a stacked alternately. The number of the polymer layers 12 and/or the number of redistribution layers 12a in the interposer RDL portion 10 are not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof. Other suitable conductive materials may be within the contemplated scope of disclosure.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm, although lesser or greater thicknesses may also be used. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12, and may extend in the x-direction (first horizontal direction) and y-direction (second horizontal direction) on an upper surface of the polymer layers 12.

An upper passivation layer 13 may be formed on the chip-side surface of the interposer RDL portion 10. The upper passivation layer 13 may include silicon oxide, silicon nitride, low-k dielectric materials such as carbon-doped oxides, extremely low-k dielectric materials such as porous carbon doped silicon dioxide, a combination thereof or other suitable material.

One or more interposer upper bonding pads 13a may be formed in the upper passivation layer 13 on the chip-side surface of interposer RDL portion 10. The upper passivation layer 13 may at least partially cover the interposer upper bonding pads 13a. That is, the interposer upper bonding pads 13a may be at least partially exposed on the chip-side surface of the interposer RDL portion 10. The interposer upper bonding pads 13a may be connected to the redistribution layers 12a. The interposer upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer 14 may be formed on the board-side surface of the interposer RDL portion 10. The lower passivation layer 14 may also include silicon oxide, silicon nitride, low-k dielectric materials such as carbon-doped oxides, extremely low-k dielectric materials such as porous carbon doped silicon dioxide, a combination thereof or other suitable material.

One or more interposer lower bonding pads 14a may be located on the board-side surface of interposer RDL portion 10. The interposer lower bonding pads 14a may be bonded to and electrically connected to the redistribution layers 12a. The interposer lower bonding pads 14a may be located in the lower passivation layer 14. The lower passivation layer 14 may at least partially cover the interposer lower bonding pads 14a. That is, the interposer lower bonding pads 14a may be at least partially exposed on the board-side surface of the interposer RDL portion 10. The interposer lower bonding pads 14a may also include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

One or more integrated passive devices (IPDs) 30 may also be located on the board-side surface of interposer RDL portion 10. The IPDs 30 may be bonded to and electrically connected to the redistribution layers 12a. The IPDs 30 may be located in the lower passivation layer 14. The IPDs 30 may include an exposed portion that projects out from the lower passivation layer 14. The IPDs 30 may include one or more electronic components such as resistors, capacitors, inductors, coils, chokes, microstriplines, impedance matching elements, baluns, etc. The IPDs 30 may be electrically coupled to the semiconductor dies 140 through the interposer 5.

As further illustrated in FIG. 1A, a plurality of C4 bumps 121 may connected to the interposer lower bonding pads 14a on the board-side surface of the interposer RDL portion 10, respectively. In at least one embodiment, the C4 bumps 121 may include underbump metallurgy (UBM) layers on the interposer lower bonding pads 14a. The C4 bumps 121 may further include a contact pad (e.g., copper/nickel contact pad) on the UBM layers and a solder bump (e.g., SnAg solder bump) on the contact pad. The C4 bumps 121 may allow the package module 120 may be connected to a substrate such as a package substrate.

The interposer molded portion 20 may have a length in the x-direction that is substantially the same as a length in the x-direction of the interposer RDL portion 10. The interposer molded portion 20 may have a width in the y-direction that is substantially the same as a width in the y-direction of the interposer RDL portion 10. The interposer molded portion 20 may have a thickness in the z-direction less than a thickness of the interposer RDL portion 10.

The interposer molded portion 20 may include a molding material layer 227 (e.g., encapsulation layer) formed on the upper passivation layer 13 of the interposer RDL portion 10. In at least one embodiment, the molding material layer 227 may be formed of a curable material that may cure to form a hard, solid structure. The molding material layer 227 may include, for example, epoxy molding compound (EMC). In at least one embodiment, the molding material layer 227 may include a polymeric material and in particular, an epoxy-based polymeric material. Other suitable molding materials may be used.

In at least one embodiment, the molding material layer 227 may have a coefficient of thermal expansion (CTE) that is substantially similar to a CTE of the interposer RDL portion 10. In at least one embodiment, the molding material layer 227 may include an added material (e.g., filler material) for improving a property of the molding material layer 227 (e.g., thermal conductivity, CTE, etc.). The added material may include, for example, metal powder, metal oxide powder, etc. Other materials in the molding material layer 227 are within the contemplated scope of the disclosure.

The interposer molded portion 20 of the interposer 5 may also include one or more local silicon interconnect (LSI) dies 200a, 200b, 200c. The molding material layer 227 may be formed around the LSI dies 200a, 200b, 200c in the x-direction and y-direction. In at least one embodiment, the LSI dies 200a, 200b, 200c may be substantially embedded in the molding material layer 227.

The LSI dies 200a, 200b, 200c may be mounted on the interposer RDL portion 10. The LSI dies 200a, 200b, 200c may be bonded to the interposer RDL portion 10, for example, by a “hybrid” bond that includes an oxide-oxide bond and a metal-metal bond. In particular, the LSI dies 200a, 200b, 200c may include lower contacts (not shown) bonded to interposer upper bonding pads 13a in the interposer RDL portion 10. The LSI dies 200a, 200b, 200c may thereby be electrically connected to the interposer upper bonding pads 13a of the interposer RDL portion 10.

The LSI dies 200a, 200b, 200c may include one or more interconnect structures 204 (e.g., metal traces and metal vias) for interconnecting the semiconductor dies in the package module 120. In particular, the LSI die 200a may include one or more interconnect structures 204 for connecting the first semiconductor die 141 to the second semiconductor die 142 and to the third semiconductor die 143 (see FIG. 1B). The LSI die 200b may include one or more interconnect structures 204 for connecting the first semiconductor die 141 to the fourth semiconductor die 144. The LSI die 200c may include one or more interconnect structures 204 for connecting the fourth semiconductor die 144 to the fifth semiconductor die 145 and to the sixth semiconductor die 146 (see FIG. 1B).

In at least one embodiment, the plurality of interconnect structures 204 in each of the LSI dies 200a, 200b, 200c may provide a high routing density die-to-die interconnect through multiple layers of sub-micron metal (e.g., copper) lines. The interconnect structures 204 may allow the LSI dies 200a, 200b, 200c to accommodate a plurality of different connection architectures (e.g., SoC to SoC, SoC to chiplet, SoC to HBM, etc.). The interconnect structures 204 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The interposer molded portion 20 may also integrate additional elements, such as a stand-alone IPDs (not shown). In at least one embodiment, the IPDs may be located in the molding material layer 227 underneath one or more of the first semiconductor die 141, second semiconductor die 142, third semiconductor die 143, fourth semiconductor die 144, fifth semiconductor die 145 and sixth semiconductor die 146 to support signal communication.

The interposer molded portion 20 may also include one or more upper RDL layers 202a (e.g., metal traces) on a chip-side surface (e.g., upper surface) of the interposer molded portion 20 (e.g., on an upper surface of the molding material layer 227). The interposer molded portion 20 may also include one or more lower RDL layers 202b and on a board-side surface (e.g., lower surface) of the interposer molded portion 20 (e.g., on an upper surface of the molding material layer 227). The interposer molded portion 20 may also include one or more through interposer vias (TIVs) 206 in the molding material layer 227. The TIVs 206 may be connected to the interposer upper bonding pads 13a of the interposer RDL portion 10, and to the semiconductor dies 140.

The upper RDL layers 202a and lower RDL layers 202b may include a wide pitch and may be connected to each other by the TIVs 206 for efficient signal and power delivery. The upper RDL layers 202a, lower RDL layers 202b and the TIVs 206 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure. With such a configuration, the interposer molded portion 20 may provide low loss of high frequency signal in high-speed transmission.

The semiconductor dies 140 may be mounted on the interposer molded portion 20. Generally, a thickness in the z-direction of each of the semiconductor dies 140 may be substantially the same. Thus, the upper surfaces of each of the first semiconductor die 141, second semiconductor die 142, third semiconductor die 143, fourth semiconductor die 144, fifth semiconductor die 145 and sixth semiconductor die 146 may be substantially coplanar (e.g., formed in the same x-y plane), and referred to collectively as the semiconductor die upper surface 140a (upper surface). In a case where the semiconductor dies 140 include upper surfaces that are not coplanar, the semiconductor die upper surface 140a may refer to the lowest upper surface of the upper surfaces of the semiconductor dies 140.

The semiconductor dies 140 may be mounted on the interposer molded portion 20, for example, by microbumps 128. The microbumps 128 may each include a copper post and a solder bump on the copper post. The microbumps 128 may be bonded (e.g., by the solder bump) to metal contacts on the chip-side surface of the interposer molded portion 20. In at least one embodiment, the microbumps 128 may be bonded to the interconnect structures 204 in the LSI dies 200a, 200b, 200c. In at least one embodiment, the microbumps 128 may be bonded to TIVs 206 in the interposer molded portion 20. In at least one embodiment, the microbumps 128 may be bonded to the upper RDL layers 202a on the chip-side surface of the interposer molded portion 20. The semiconductor dies 140 may, therefore, be connected to the redistribution layers 12a in the interposer RDL portion 10 through the microbumps 128.

A package module underfill layer 129 may be formed (e.g., individually or connectively) under and around each of the semiconductor dies 140. The package module underfill layer 129 may also be formed around the microbumps 128. The package module underfill layer 129 may thereby fix each of the semiconductor dies 140 to the interposer molded portion 20. The package module underfill layer 129 may be formed of an epoxy-based polymeric material.

Each of the semiconductor dies 140 may include, for example, a singular semiconductor die, a system on chip (SOC) die, or a system on integrated chips (SoIC) die, and may be implemented by chip on wafer on substrate (CoWoS) technology or integrated fan-out on substrate (INFO-oS) technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, an inverted AND (NAND) die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure.

In at least one embodiment, the first semiconductor die 141 may include a primary die (e.g., SOC die), and the second semiconductor die 142 and third semiconductor die 143 may each include an ancillary die (e.g, memory/SOC die, HBM die, etc.). In at least one embodiment, the fourth semiconductor die 144 may include a primary die (e.g., SOC die), and the fifth semiconductor die 145 and the sixth semiconductor die 146 may each include an ancillary die (e.g, memory/SOC die, HBM die, etc.).

The package module 120 may also include an upper molding material layer 127 formed around the semiconductor dies 140. The upper molding material layer 127 may also be formed on and around the package module underfill layer 129. The upper molding material layer 127 may have an outer sidewall that is substantially aligned with the outer sidewall of the interposer 5.

In at least one embodiment, the upper molding material layer 127 may be formed on sidewalls (inner sidewall and outer sidewall) of each of the semiconductor dies 140. The upper molding material layer 127 may be formed between and bonded to the sidewalls of each of the semiconductor dies 140. The upper molding material layer 127 may also be bonded to the chip-side surface of the interposer molded portion 20 and the package module underfill layer 129.

As illustrated in FIG. 1A, the upper molding material layer 127 may include an upper surface that is substantially uniform (e.g., flat). The upper surface of the upper molding material layer 127 may include a recessed upper surface 300 that is recessed in the z-direction from the semiconductor die upper surface 140a. In at least one embodiment, the recessed upper surface 300 may constitute an entirety of an upper surface of the upper molding material layer 127. In at least one embodiment, the recessed upper surface 300 may constitute less than an entirety of an upper surface of the upper molding material layer 127.

The recessed upper surface 300 of the upper molding material layer 127 may include an inner recessed surface portion 300a between the semiconductor dies 140. The recessed upper surface 300 of the upper molding material layer 127 may also include an outer recessed surface portion 300b outside the semiconductor dies 140 in a horizontal, lateral or x-y direction.

In at least one embodiment, the upper molding material layer 127 may be formed of a curable material that may cure to form a hard, solid structure. The upper molding material layer 127 may include, for example, epoxy molding compound (EMC). In at least one embodiment, the upper molding material layer 127 may include a material that is substantially similar to the package module underfill layer 129, and or substantially similar to the molding material layer 227 in the interposer molded portion 20. In at least one embodiment, the upper molding material layer 127 may include a polymeric material and in particular, an epoxy-based polymeric material. Other suitable molding materials may be within the contemplated scope of disclosure.

In at least one embodiment, the upper molding material layer 127 may have a CTE that is substantially similar to a CTE of the interposer molded portion 20 and/or a CTE of the interposer RDL portion 10. In at least one embodiment, the upper molding material layer 127 may include an added material (e.g., filler material) for improving a property of the upper molding material layer 127 (e.g., thermal conductivity, CTE, etc.). The added material may include, for example, metal powder, metal oxide powder, etc. Other materials in the upper molding material layer 127 are within the contemplated scope of the disclosure.

The package module 120 may also include a backside metal layer 400 on the upper surface of the upper molding material layer 127. The backside metal layer 400 may include an inner backside metal layer portion 400a on the inner recessed surface portion 300a of the recessed upper surface 300 of the upper molding material layer 127. The backside metal layer 400 may also include an outer backside metal layer portion 400b on the outer recessed surface portion 300b of the recessed upper surface 300 of the upper molding material layer 127. The backside metal layer 400 may also include a semiconductor die covering portion 400c on the semiconductor die upper surface 140a of the semiconductor dies 140. The backside metal layer 400 may or may not include a semiconductor die sidewall covering portion 400d on a sidewall (e.g., exposed sidewall above the recessed upper surface 300) of each of the semiconductor dies 140.

The backside metal layer 400 may have a substantially uniform thickness throughout. In at least one embodiment, the backside metal layer 400 may have a thickness in a range from 0.1 μm to 1.5 μm. In at least one embodiment, a thickness of the semiconductor die sidewall covering portion 400d may be less than a thickness of the remainder of the backside metal layer 400. The backside metal layer 400 may include, for example, one or more layers of metal material such as copper, aluminum, nickel, titanium, a combination thereof or other suitable metals. In at least one embodiment, the backside metal layer 400 may include one or more layers of aluminum, titanium, nickel vanadium (NiV) and gold.

In FIG. 1B, shading and dashed lines are used to indicate a location of the semiconductor dies 140 that may be located underneath the backside metal layer 400. As illustrated in FIG. 1B, the backside metal layer 400 may be formed over a substantially entire upper surface of the package module 120 including the upper molding material layer 127 and the semiconductor dies 140. In particular, the backside metal layer 400 may have a pattern in which an outer edge of the backside metal layer 400 is substantially aligned with an outer edge of the upper molding material layer 127 around an entire outer periphery of the package module 120.

FIG. 1C is a vertical cross-sectional view of a portion of the package module 120 according to one or more embodiments. In particular, FIG. 1C illustrates the inner recessed surface portion 300a and outer recessed surface portion 300b of the recessed upper surface 300 of the upper molding material layer 127. FIG. 1C also illustrates the inner backside metal layer portion 400a on the inner recessed surface portion 300a, and the outer backside metal layer portion 400b on the outer recessed surface portion 300b. FIG. 1C also illustrates the semiconductor die covering portion 400c on the semiconductor die upper surface 140a, and the semiconductor die sidewall covering portion 400d on the sidewalls of the first semiconductor die 141 and second semiconductor die 142.

As illustrated in FIG. 1C, the recessed upper surface 300 of the upper molding material layer 127 may have a height H1 (e.g., from the upper surface of the interposer molded portion 20) that is substantially uniform. In particular, the height H1 of the recessed upper surface 300 may be substantially the same for the inner recessed surface portion 300a and the outer recessed surface portion 300b. The semiconductor die upper surface 140a may have a height H2 (e.g., from the upper surface of the interposer molded portion 20) that is substantially uniform across all of the semiconductor dies 140. As illustrated in FIG. 1C, the height H2 of the semiconductor die upper surface 140a may be greater than the height H1 of the recessed upper surface 300. In at least one embodiment, a depth D1 of the recessed upper surface 300 (e.g., H2−H1) from the semiconductor die upper surface 140a may be less than 10 μm.

A space between the each of the semiconductor dies 140 may have a length L1 in a range from 1 μm to 5000 μm. The length L1 may also constitute a length of the inner recessed surface portion 300a of the recessed upper surface 300. The length L1 may also constitute a length of the inner backside metal layer portion 400a.

In at least one embodiment, the semiconductor die sidewall covering portion 400d may connect the semiconductor die covering portion 400c to the inner backside metal layer portion 400a. A length in the z-direction of the semiconductor die sidewall covering portion 400d may be substantially equal to the depth D1 (e.g., H2−H1) of the recess surface 300 (e.g., less than about 10 μm). A plurality of gaps G may be formed between opposing faces of the semiconductor die sidewall covering portion 400d of each of the semiconductor dies 140.

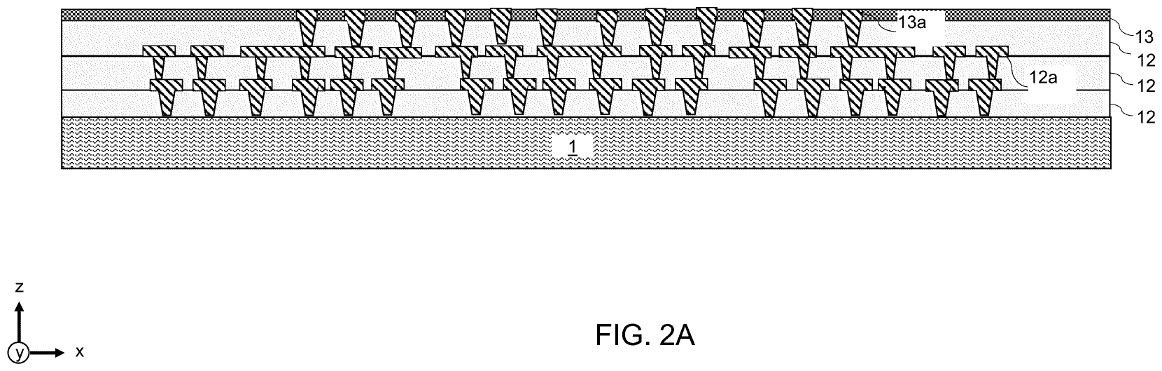

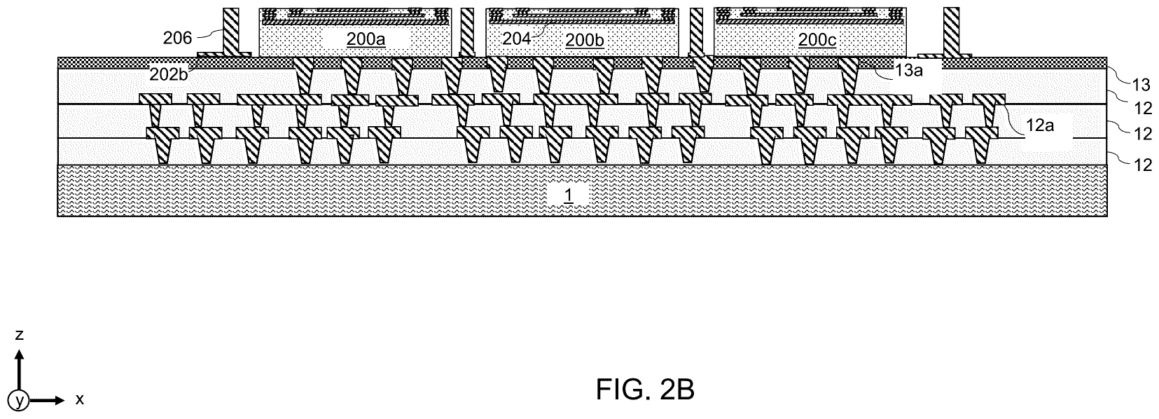

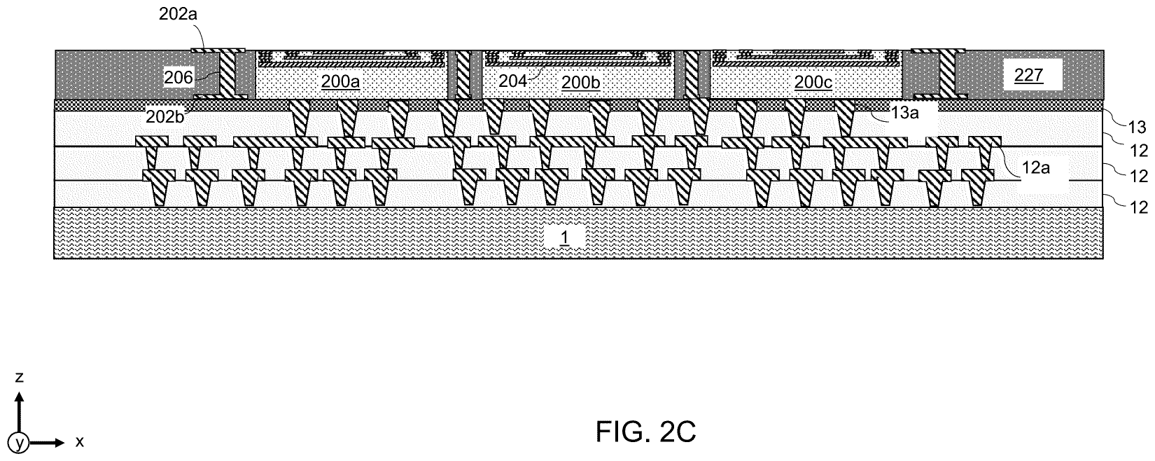

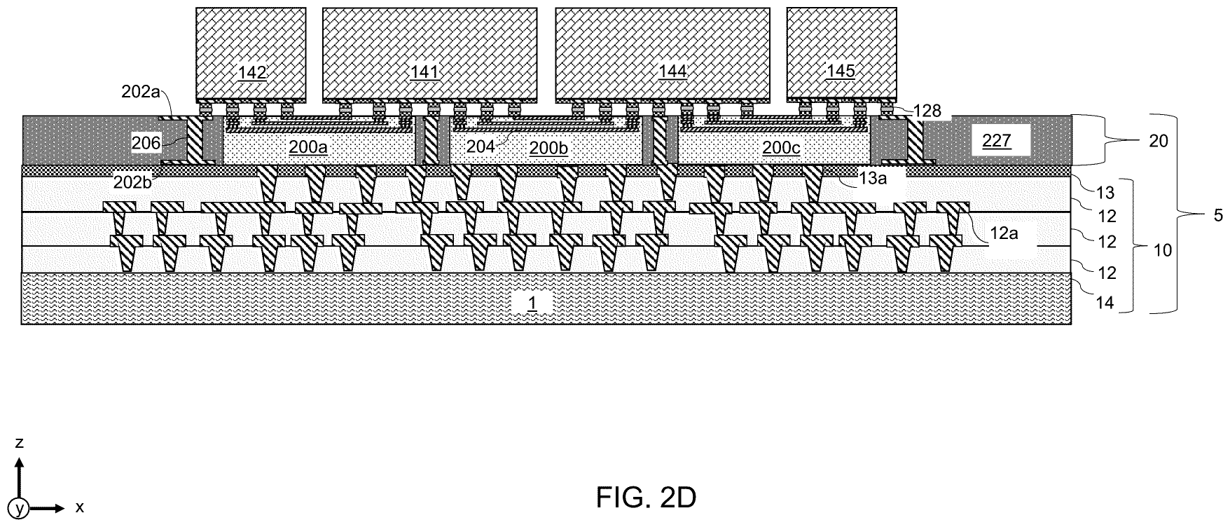

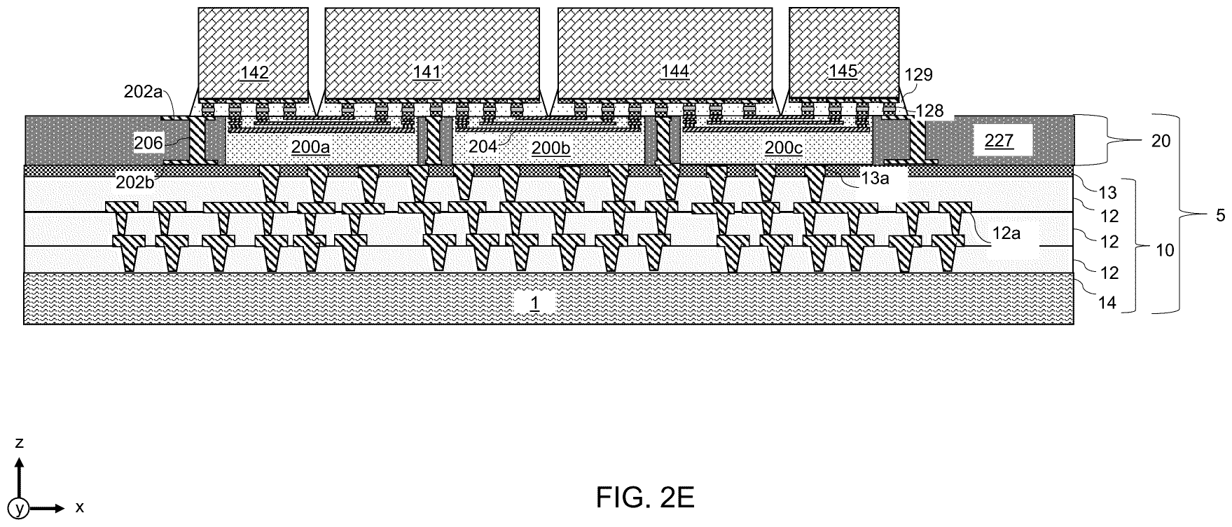

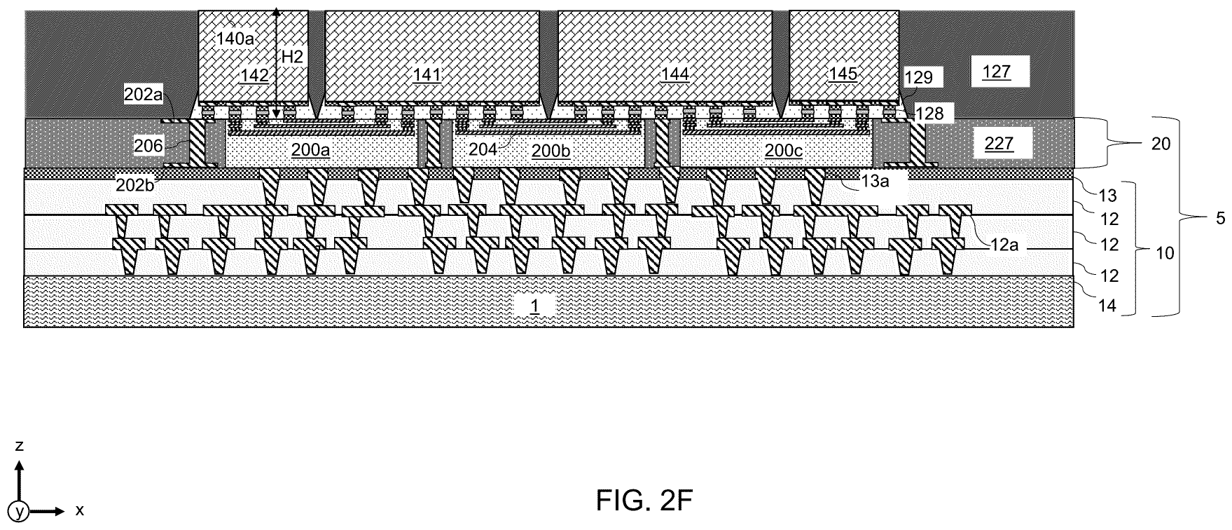

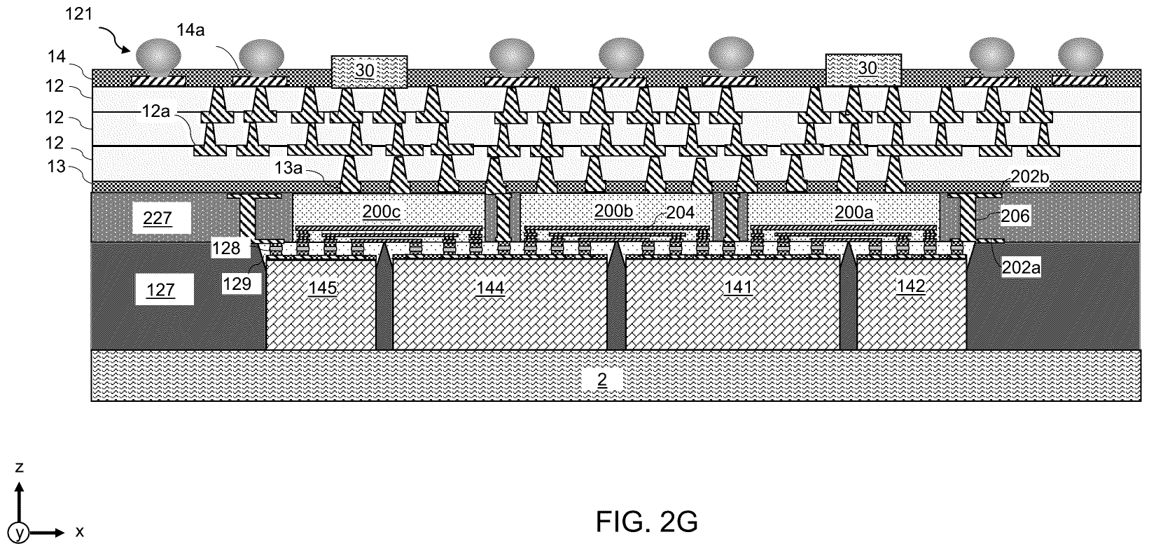

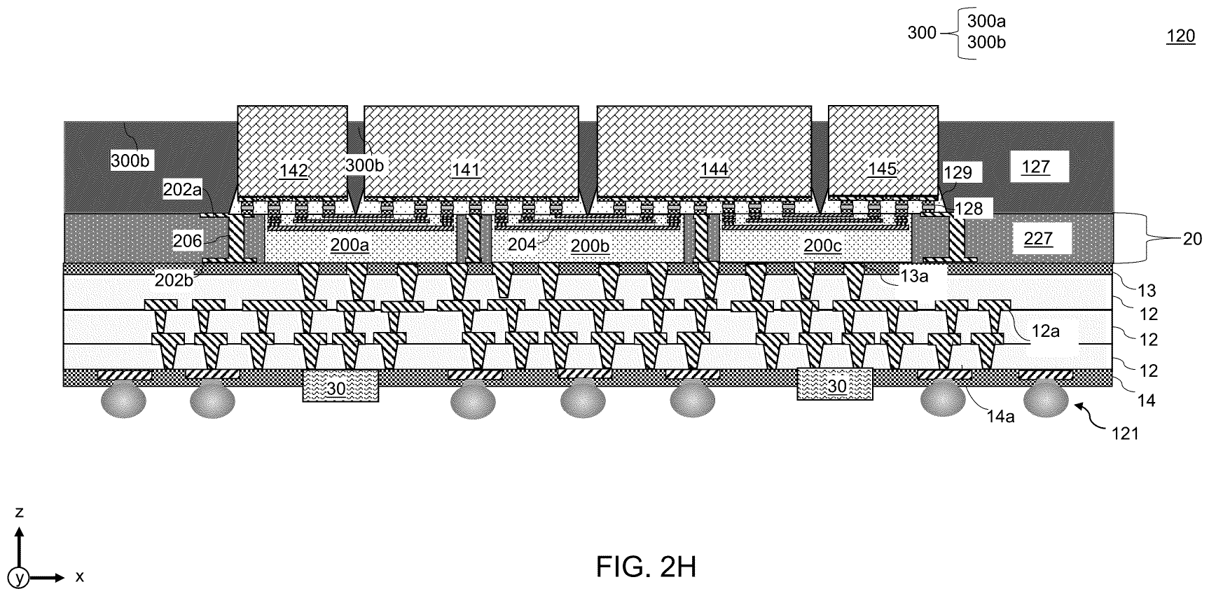

FIGS. 2A-2H illustrate various intermediate structures in a method of forming the package module 120 according to one or more embodiments. FIG. 2A is a vertical cross-sectional view of an intermediate structure including a portion of the interposer RDL portion 10 (e.g., organic interposer) formed on a first carrier substrate 1 (e.g., carrier wafer) according to an embodiment of the present invention. The lower passivation layer 14 and interposer lower bonding pads 14a of the interposer RDL portion 10 may be formed later in the method of forming the package module 120.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used.

An adhesive layer (not shown) may be applied to the top surface of the first carrier substrate 1. In one embodiment, the first carrier substrate 1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. For example, the LTHC layer may include Light-To-Heat Conversion Release Coating (LTHC) Ink™ that may be commercially available. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

A plurality of dielectric layers 12 and plurality of redistribution layers 12a may be alternately formed on the first carrier substrate 1 (e.g., on the adhesive layer on the first carrier substrate 1). It should be noted that although FIG. 2A illustrates three dielectric layers 12 and three redistribution layers 12a, more or fewer dielectric layers 12 and redistribution layers 12a are contemplated by the present disclosure.

Each dielectric layer 12 may each be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The redistribution layer 12a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 2A, the interposer upper bonding pads 13a may then be formed on the uppermost dielectric layer 12. The interposer upper bonding pads 13a may include any metallic material that may be bonded to a solder material. The interposer upper bonding pads 13a may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process so as to form the interposer upper bonding pads 13a. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

In at least one embodiment, the interposer upper bonding pads 13a may include an underbump metallurgy (UBM) layer stack deposited over the adhesive layer. The order of material layers within the UBM layer stack may be selected such that solder material portions may be subsequently bonded to portions of the bottom surface of the UBM layer stack. Layer stacks that may be used for the UBM layer stack include, but are not limited to, stacks of Cr/Cr-Cu/Cu/Au, Cr/Cr-Cu/Cu, TiW/Cr/Cu, Ti/Ni/Au, and Cr/Cu/Au. Other suitable materials are within the contemplated scope of disclosure. The thickness of the UBM layer stack may be in a range from 5 microns to 60 microns, such as from 10 microns to 30 microns, although lesser and greater thicknesses may also be used. A photoresist layer may be applied over the UBM layer stack, and may be lithographically patterned to form an array of discrete patterned photoresist material portions. An etch process may be performed to remove unmasked portions of the UBM layer stack. The etch process may be an isotropic etch process or an anisotropic etch process. Remaining portions of the UBM layer stack may form the interposer upper bonding pads 13a. In at least one embodiment, the interposer upper bonding pads 13a may be arranged as a two-dimensional array, which may be a two-dimensional periodic array such as a rectangular periodic array. In at least one embodiment, the interposer upper bonding pads 13a may be formed as controlled collapse chip connection (C4) bump structures.

The upper passivation layer 13 may then be formed on the chip-side surface of the interposer RDL portion 10 and over the interposer upper bonding pads 13a. The upper passivation layer 13 may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, chemical mechanical polishing (CMP), etc.) so as to form the upper passivation layer 13.

FIG. 2B is a vertical cross-sectional view of an intermediate structure including the LSI dies 200a, 200b, 200c according to one or more embodiments. The lower RDL layers 202b may be formed on the upper passivation layer 13 by a photolithographic process. In particular, a metal layer may be deposited (e.g, by CVD, PVD or other suitable deposition process) on the upper passivation layer 13. The metal layer may then be patterned by a photolithographic process so as to form the lower RDL layers 202b. The photolithographic process may include forming a patterned photoresist mask (not shown) on the metal layer, and etching (e.g., wet etching, dry etching, etc.) the exposed upper surface of the metal layer through openings in the photoresist mask. The photoresist mask may be subsequently removed by ashing, dissolving the photoresist mask or by consuming the photoresist mask during the etch process.

The TIVs 206 may then be formed in one or more electroplating processes. In one or more embodiments, a seed layer (not shown) may be formed on the upper passivation layer 13. A metal material may then be electroplated on the seed layer to form the TIVs 206. The metal material for electroplating may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The LSI dies 200a, 200b, 200c may then be placed on the interposer RDL portion 10, for example, by using an electromechanical pick-and-place (PNP) machine. Each of the LSI dies 200a, 200b, 200c may be bonded, for example, to the interposer RDL portion 10 including a respective subset of the interposer upper bonding pads 13a by a hybrid bonding process (e.g., metal-metal bonding, oxide-oxide bonding). It should be noted that the LSI dies 200a, 200b, 200c may be mounted on the interposer RDL portion 10 before or after the forming of the TIVs 206.

FIG. 2C is a vertical cross-sectional view of an intermediate structure including the molding material layer 227 according to one or more embodiments. The molding material layer 227 (e.g., encapsulant layer) may be formed by a sequence of an over-molding process and a planarization process. In particular, the molding material layer 227 may include an epoxy polymer material (e.g., an epoxy molding compound (EMC). The molding material layer 227 may be formed on the interposer RDL portion 10 and fill in the gaps between the LSI dies 200a, 200b, 200c and the TIVs 206. The molding material layer 227 may encapsulate (e.g., in the x-direction and y-direction) the LSI dies 200a, 200b, 200c and the TIVs 206. The molding material layer 227 may be formed, for example, by a deposition process such as CVD, PECVD, PVD, spin coating, lamination or other suitable deposition technique.

The molding material layer 227 may be deposited so as to completely cover the LSI dies 200a, 200b, 200c and the TIVs 206. After the molding material layer 227 has cured, a planarization process may then be used to make an upper surface of the molding material layer 227 coplanar with an upper surface of the LSI dies 200a, 200b, 200c and an upper surface of the TIVs 206. In particular, the planarization process may be performed on the upper surface of the molding material layer 227 until an upper surface of the LSI dies 200a, 200b, 200c and an upper surface of the TIVs 206 are exposed. The planarization process may include, for example, a mechanical grinding process and/or a CMP process. The upper RDL layers 202a may then be formed on the upper surface of the molding material layer 227 in a manner similar to the forming of the lower RDL layers 202b, to complete the formation of the interposer molded portion 20.

FIG. 2D is a vertical cross-sectional view of an intermediate structure including the first semiconductor die 141, second semiconductor die 142, fourth semiconductor die 144 and fifth semiconductor die 145 on the interposer molded portion 20 according to one or more embodiments. Although not illustrated in FIG. 2D, all of the semiconductor dies 140 (i.e., third semiconductor die 143, sixth semiconductor die 146) may be mounted concurrently on the interposer molded portion 20 in the same process.

Each of the semiconductor dies 140 may be bonded to the interposer molded portion 20 by one or more microbumps 128. In at least one embodiment, the microbumps 128 may include a two-dimensional array of microbumps 128, and each of the semiconductor dies 140 may be attached to the interposer upper bonding pads 13a by C2 bonding, (e.g., solder bonding). A C2 bonding process that reflows the solder portions of the microbumps 128 may be performed after the microbumps 128 on the semiconductor dies 140 are disposed over corresponding bonding pads in the upper surface of the interposer molded portion 20. In particular, the microbumps 128 may be bonded to the interconnect structures 204 in the LSI dies 200a, 200b, 200c, to the TIVs 206 in the interposer molded portion 20 and/or to the upper RDL layers 202a on the chip-side surface of the interposer molded portion 20.

FIG. 2E is a vertical cross-sectional view of an intermediate structure including the package module underfill layer 129 according to one or more embodiments. The package module underfill layer 129 may be applied by depositing and/or injecting an epoxy-based polymeric material onto the interposer molded portion 20. The epoxy-based polymeric material may be applied on the interposer molded portion 20 so as to be formed under the semiconductor dies 140 and around the microbumps 128. In at least one embodiment, the epoxy-based polymeric material may fill substantially all of the gaps between the semiconductor dies 140 and the interposer molded portion 20. The package module underfill layer 129 may then be cured, for example, in a box oven for about 90 minutes at about 150° C. to provide the package module underfill layer 129 with a sufficient stiffness and mechanical strength.

FIG. 2F illustrates a vertical cross-sectional view of an intermediate structure including the upper molding material layer 127 according to one or more embodiments. The upper molding material layer 127 may be formed by dispensing a liquid molding material (e.g., EMC, epoxy molding material) onto the intermediate structure of FIG. 2E by a suitable dispensing tool. The upper molding material layer 127 may be dispensed onto the intermediate structure so as to have a height greater than the height H2 of the semiconductor die upper surface 140a.

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the interposer molded portion 20, a size of the interposer molded portion 20, sizes of the semiconductor dies 140, etc.

In at least one embodiment, the molding material of the upper molding material layer 127 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around the semiconductor dies 140. The low viscosity may also help to avoid the formation of voids in the upper molding material layer 127. In at least one embodiment, the upper molding material layer 127 may be substantially free of voids.

After the upper molding material layer 127 has been adequately cured, the upper molding material layer 127 may be planarized so as to make the upper surface of the upper molding material layer 127 to be substantially coplanar with the semiconductor die upper surface 140a. The upper molding material layer 127 may be planarized, for example, by grinding, chemical mechanical polishing (CMP) or other suitable planarization technique.

FIG. 2G illustrates a vertical cross-sectional view of an intermediate structure including the plurality of C4 bumps 121 and the IPDs 30, according to one or more embodiments. After the upper molding material layer 127 has been cured and planarized (e.g., by grinding, CMP, etc.), a second carrier substrate 2 may be attached to the intermediate structure of FIG. 2F. In particular, the second carrier substrate 2 may be attached to the upper surface of the molding material layer 127 and the semiconductor die upper surface 140a of the semiconductor dies 140.

The intermediate structure of FIG. 2F may then be inverted and the first carrier substrate 1 may be detached from the lower polymer layer 12 of the interposer RDL portion 10. The first carrier substrate 1 may be detached from the interposer RDL portion 10, for example, by deactivating the adhesive layer (not shown) adhering the first carrier substrate 1 to the interposer RDL portion 10. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

The interposer lower bonding pads 14a may then be formed on the lower polymer layer 12 of the interposer RDL portion 10. The interposer lower bonding pads 14a may be formed using substantially the same materials and substantially the same photolithographic processes as described above for the interposer upper bonding pads 13a. The lower passivation layer 14 may then be formed on the lower polymer layer 12 of the interposer RDL portion 10 and over the interposer lower bonding pads 14a. The lower passivation layer 14 may be formed using the same materials and processes described above for the upper passivation layer 13.

The lower passivation layer 14 may then be etched by a suitable etching process (e.g., by wet etching, dry etching, etc.) to form openings over the interposer lower bonding pads 14a and expose a surface of the interposer lower bonding pads 14a. The etching process may also form IPD openings in the lower passivation layer 14 for the IPDs 30.

The IPDs 30 may then be mounted on the lower polymer layer 12 through the IPD openings in the lower passivation layer 14. The IPDs 30 may be mounted on the lower polymer layer 12 so as to contact the metal interconnects 12a in the lower polymer layer 12. The IPDs 30 may be mounted, for example, by using an electromechanical pick-and-place (PNP) machine. The plurality of C4 bumps 121 may then be formed on the intermediate structure. The C4 bumps 121 may include, for example, solder bumps formed in the openings in the lower passivation layer 14 over the interposer lower bonding pads 14a, for example, by an electroplating process. The plurality of C4 bumps 121 may contact the interposer lower bonding pads 14a through the openings in the lower passivation layer 14. In at least one embodiment, the C4 bumps 121 may be formed by forming one or more underbump metallization (UBM) layers (not shown) on the interposer lower bonding pads 14a, forming contact pads on the UBM layers, and forming the solder bumps on the contact pads.

FIG. 2H is a vertical cross-sectional view of an intermediate structure including the recessed upper surface 300 according to one or more embodiments. After the mounting of the IPDs 30 and the forming of the C4 bumps 121, the second carrier substrate 2 may be detached from the intermediate structure using a process similar to the process used to detach the first carrier substrate 1 described above.

The upper surface of the upper molding material layer 127 may then be etched to form the recessed upper surface 300. A suitable etching process (e.g., wet etching, dry etching) may be used to recess the upper surface of the molding material layer 127 from the semiconductor die upper surface 140a of the semiconductor dies 140. After the upper surface has been adequately recessed (e.g., to a depth less than about 10 μm), the etching process may be stopped and the intermediate structure may be cleaned (e.g., using solvent, etc.) and polished.

The backside metal layer 400 (see FIG. 1A) may then be formed on the recessed upper surface 300 and on the semiconductor die upper surface 140a. The backside metal layer 400 may be formed by conformally depositing (e.g., by CVD, PVD or other suitable deposition technique) a metal material on the recessed upper surface 300 and on the semiconductor die upper surface 140a. In at least one embodiment, the metal material may be deposited by a sputtering process. The metal material may then optionally be patterned (e.g., etched) by a photolithographic process to form the back side metal layer 400. The photolithographic process may include forming a patterned photoresist mask (not shown) on the metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

After the formation of the backside metal layer 400, a singulation process (e.g., dicing, sawing, etc.) may be performed. The singulation process may separate the package module 120 from surrounding wafer material and complete the formation of the package module 120.

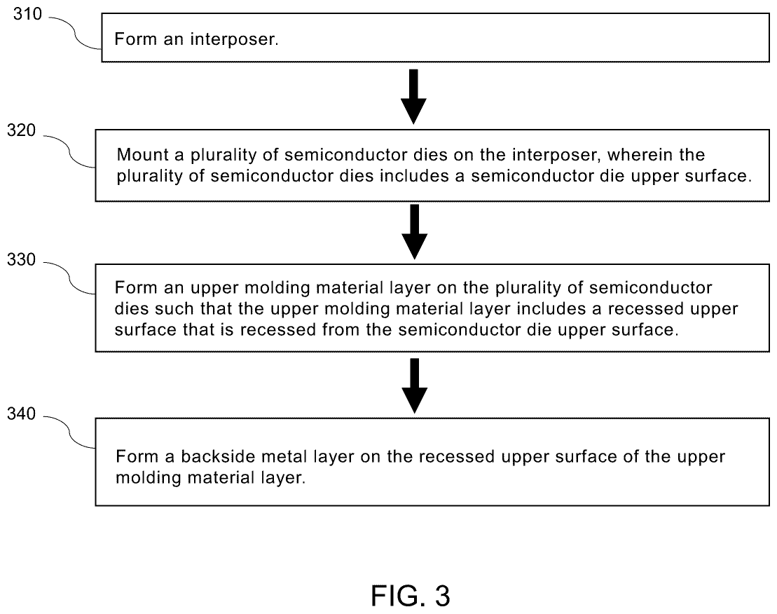

FIG. 3 is a flow chart illustrating a method of forming the package module 120 according to one or more embodiments. Step 310 includes forming an interposer. Step 320 includes mounting a plurality of semiconductor dies on the interposer, wherein the plurality of semiconductor dies includes a semiconductor die upper surface. Step 330 includes forming an upper molding material layer on the plurality of semiconductor dies such that the upper molding material layer includes a recessed upper surface that is recessed from the semiconductor die upper surface. Step 340 includes forming a backside metal layer on the recessed upper surface of the upper molding material layer.

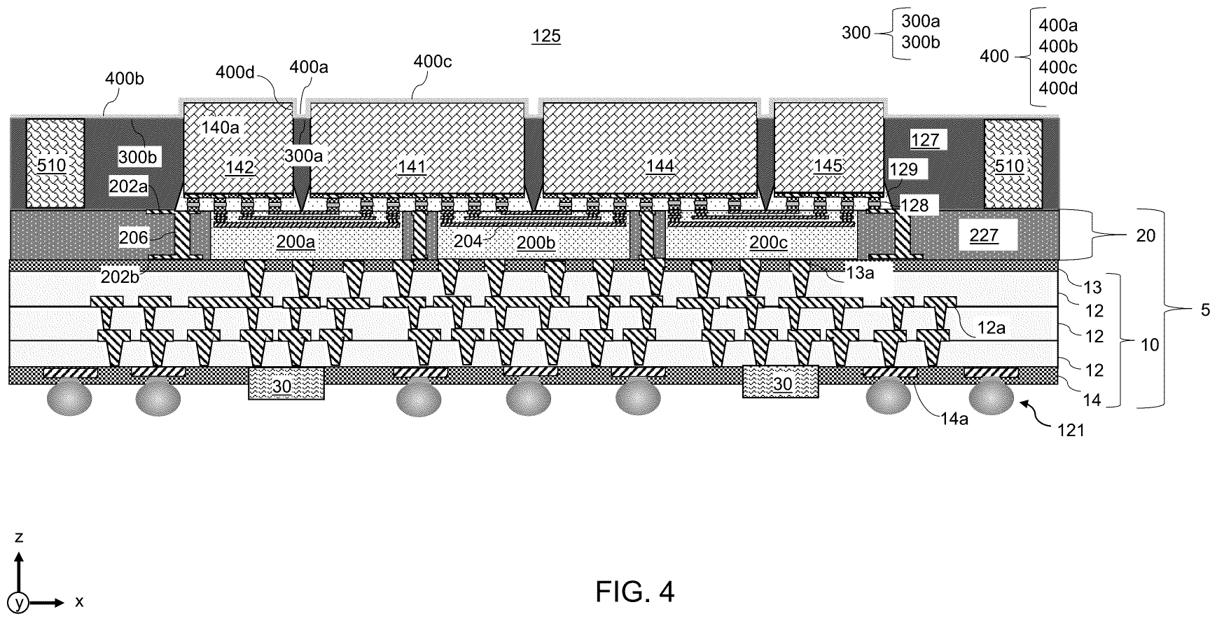

FIG. 4 is a vertical cross-sectional view of the package module 125 having a first alternative design according to one or more embodiments. The first alternative design is substantially the same as the original design in FIG. 1A, and may be formed in a manner similar to the manner of forming the original design. However, in the first alternative design, the package module 125 may include one or more dummy dies 510 in the upper molding material layer 127. The dummy dies 510 may be mounted on the interposer molded portion 20 and have an upper surface substantially coplanar with the recessed upper surface 300 of the upper molding material layer 127. The backside metal layer 400 may be formed on the upper surface of the dummy dies 510.

The dummy dies 510 may be non-functional, and may be formed of a variety of materials such as silica, glass, etc. In at least one embodiment, the dummy dies 510 may have a CTE substantially the same as the upper molding material layer 127. The dummy dies 510 may have a size (e.g., length in the x-direction, width in the y-direction, thickness in the z-direction) that is substantially the same as one of the semiconductor dies 140. The dummy dies 510 may be added, for example, to provide structural stability.

The dummy dies 510 may be mounted on the interposer molded portion 20 prior to the forming of the upper molding material layer 127. The dummy dies 510 may be fixed to the interposer molded portion 20, for example, by an adhesive (e.g., a silicone adhesive or an epoxy adhesive).

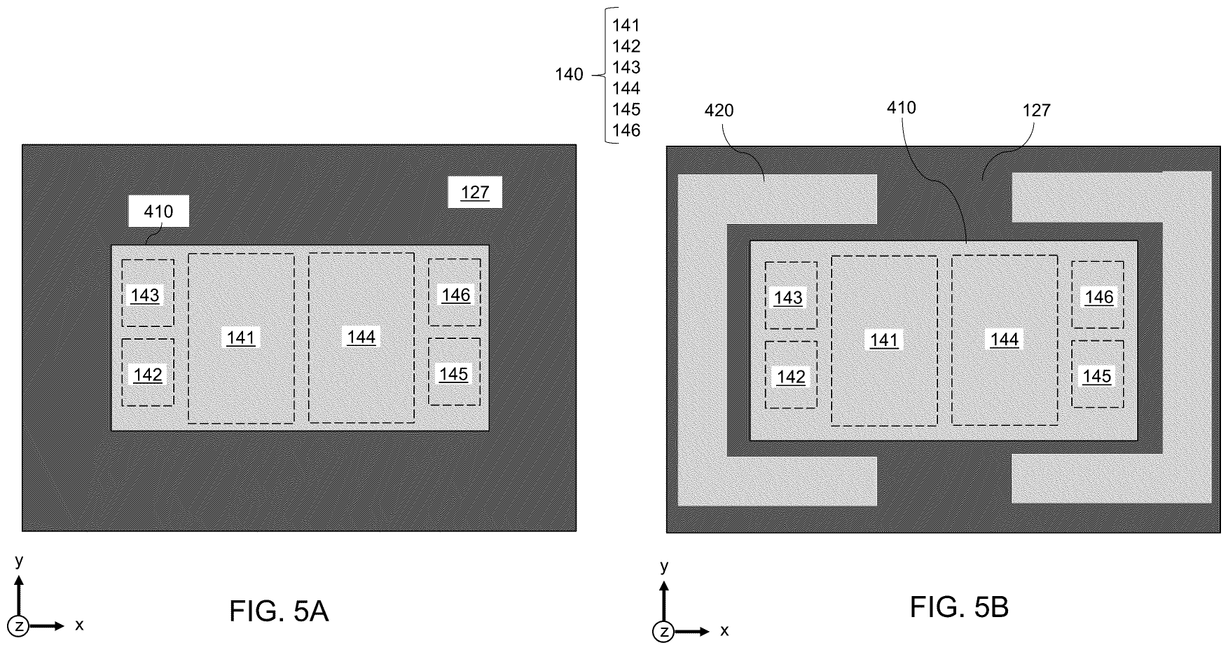

FIGS. 5A-5B are plan views of alternative designs of the backside metal layer 400 according to one or more embodiments. In FIGS. 5A-5B, shading and dashed lines are used to indicate a location of the semiconductor dies 140 that may be located underneath the backside metal layer 400.

FIG. 5A is a plan view of a first alternative design (e.g., pattern) of the backside metal layer 400 according to one or more embodiments. In the first alternative design, the backside metal layer 400 may be formed on less than an entirety of the upper molding material layer 127. In particular, the backside metal layer 400 may include a central portion 410 on the semiconductor dies 140. The central portion 410 of the backside metal layer 400 may include the inner backside metal layer portion 400a (see FIG. 1C) on the inner recessed surface portion 300a of the recessed upper surface 300 of the upper molding material layer 127. The central portion 410 of the backside metal layer 400 may also include part of the outer backside metal layer portion 400b (see FIG. 1C) on the outer recessed surface portion 300b of the recessed upper surface 300 of the upper molding material layer 127. The central portion 410 of the backside metal layer 400 may also include the semiconductor die covering portion 400c and the semiconductor die sidewall covering portion 400d (see FIG. 1C).

However, in contrast to the original design in FIG. 1B, in the first alternative design, the outer backside metal layer portion 400b may be formed on less than an entirety of the outer recessed surface portion 300b of the recessed upper surface 300 of the upper molding material layer 127. That is, the central portion 410 may include only a part of the outer backside metal layer portion 400b (see FIG. 1C).

FIG. 5B is a plan view of a second alternative design of the backside metal layer 400 according to one or more embodiments. In the second alternative design, the backside metal layer 400 may include the central portion 410 on the semiconductor dies 140, similar to the first alternative design in FIG. 5A. However, in the second alternative design, the backside metal layer 400 may additionally include a peripheral portion 420 located around an outer periphery of the central portion 410 of the backside metal layer 400. In at least one embodiment, the peripheral portion 420 may have a partial frame shape that is formed around part of the outer periphery of the semiconductor dies 140.

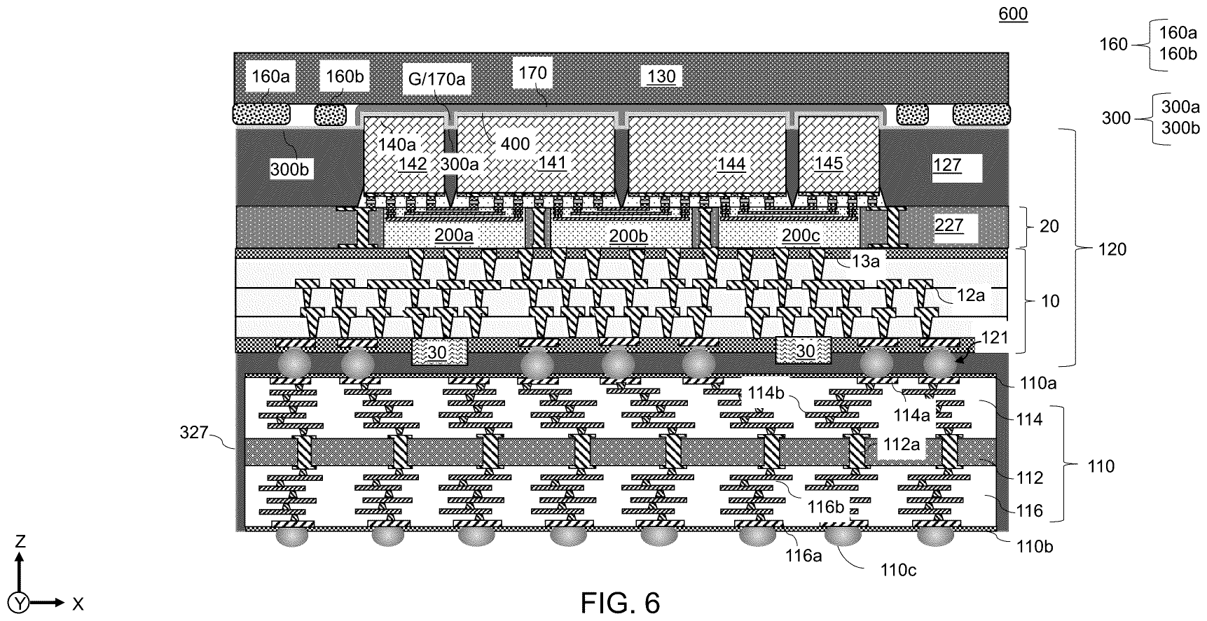

FIG. 6 is a vertical cross-sectional view of a package structure 600 according to one or more embodiments. As illustrated in FIG. 6, the package structure 600 may include a package substrate 110, the package module 120 on the package substrate 110, and a package lid 130 on the package module 120.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may partially cover the package substrate upper bonding pads 114a. The upper passivation layer 114a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on an lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 110c may be formed on the board-side surface of the package substrate lower dielectric layer 116. The solder balls 110c may allow the package structure 600 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b.

The package module 120 may be connected to the package substrate 110 by the C4 bumps 121 on the board-side surface of the interposer RDL portion 10. In particular, the C4 bumps 121 may be bonded (e.g., using solder reflow, compression bonding, thermocompression bonding, etc.) to the package substrate upper bonding pads 114a of the package substrate 110. As illustrated in FIG. 6, the package substrate 110 may have a length in the x-direction that is less than a length of the package module 120 in the x-direction. The package substrate 110 may also have a width in the y-direction that is less than a width of the package module 120 in the y-direction.

The package structure 600 may further include a thermal interface material (TIM) layer 170 on the package module 120. The TIM layer 170 may be located on the backside metal layer 400 of the package module 120. The TIM layer 170 may be located over the semiconductor dies 140 and around a portion of the semiconductor dies 140 that extends above the upper molding material layer 127. The TIM layer 170 may also including a TIM layer projecting portion 170a that projects from a bottom of the TIM layer 170 and into the gap G between the semiconductor dies 140. In at least one embodiment, the TIM layer projecting portion 170a may contact each of the inner backside metal layer portion 400a, the semiconductor die covering portion 400c and the semiconductor die sidewall covering portion 400d (see FIG. 1C). In at least one embodiment, the TIM layer projecting portion 170a may substantially fill the gap G.

The TIM layer 170 may include, for example, a TIM paste, a gel TIM, graphite TIM, metal TIM, solder TIM and a carbon nanotube TIM. In at least one embodiment, the TIM layer 170 may include a film-type TIM layer. In at least one embodiment, the TIM layer 170 may include an indium base, silver base and/or solder base. Other types of TIMs are within the contemplated scope of this disclosure. In at least one embodiment, the TIM layer 170 may have a thickness (e.g., a greatest thickness in the z-direction) in a range from 100 μm to 300 μm.

The TIM layer 170 may be formed on the package module 120 to dissipate of heat generated during operation of the package structure 600 (e.g., operation of the semiconductor dies 140). The TIM layer 170 may be attached to the package module 120, for example, by a thermally conductive adhesive. The TIM layer 170 may have a low bulk thermal impedance and high thermal conductivity. The bond-line-thickness (BLT) (e.g., a distance between the package lid 130 and the package module 120) may be less than about 100 μm, although greater or lesser distances may be used.

The package lid 130 may be located on the TIM layer 170 and connected to the package module 120. The package lid 130 may be fixed to the package module 120 by an adhesive layer 160. The package lid 130 may contact at least a portion of the TIM layer 170. In one or more embodiments, the package lid 130 may directly contact an entire upper surface of the TIM layer 170. The TIM layer 170 may be compressed between the package lid 130 and the package module 120. In particular, the TIM layer 170 may be compressed between the package lid 130 and the backside metal layer 400 of the package module 120.

The package lid 130 may be formed, for example, of metal, ceramic or polymer material. The package lid 130 may have a plate shape (e.g., planar shape) and be substantially parallel to an upper surface of the package substrate 110. The package lid 130 may extend, for example, in an x-y plane in FIG. 6. The package lid 130 may include an outer sidewall that is substantially aligned with an outer sidewall of the upper molding material layer 127. The package lid 130 may include a central portion that is substantially aligned in the z-direction with a central portion of the package module 120. The package lid 130 may include an upper surface and a bottom surface that are substantially planar. Alternatively, the package lid 130 may also include a bottom step region (not shown) that may project from the bottom surface and contact the TIM layer 170.

The adhesive layer 160 may be bonded to the backside metal layer 400 and/or the upper surface of the upper molding material layer 127. The adhesive layer 160 may include an adhesive foot portion 160a near the sidewall of the package module 120. The adhesive foot portion 160a may bond the package lid 130 to the package module 120. The adhesive layer 160 may also include an adhesive wall portion 160b between the adhesive foot portion 160a and the semiconductor dies 140. The adhesive wall portion 160b may also bond the package lid 130 to the package module 120. The adhesive wall portion 160b may also serve to contain a spread of the TIM layer 170 as the TIM layer 170 is compressed between the package lid 130 and the package module 120. A thickness of the adhesive layer 160 may be in a range from 50 μm to 200 μm. The adhesive layer 160 may include, for example, a silicone adhesive (e.g., containing aluminum oxide, zinc oxide, resin, etc.) or an epoxy adhesive. Other suitable adhesives may be used. The adhesive layer 160 may contact the backside metal layer or the recessed upper surface of the upper molding material layer.

The package structure 600 may further include a lower molding material layer 327 on the package substrate 110. The lower molding material layer 327 may be formed between the package module 120 and the package substrate 110 and serve to bond the package module 120 to the package substrate 110. The lower molding material layer 327 may be formed around the C4 bumps 121 and substantially fill the space between the package module 120 and the package substrate 110. The lower molding material layer 327 may also be formed on a sidewall of the package substrate 110. The lower molding material layer 327 may have an outer sidewall that is substantially aligned with the sidewall of the interposer RDL portion 10. A bottom of the lower molding material layer 327 may be substantially aligned with the package substrate lower passivation layer 110b. The lower molding material layer 327 may include, for example, a polymeric material and in particular, an epoxy-based polymeric material (e.g., EMC).

The package structure 600 may be formed, for example, by attaching the package substrate 110 to the package module 120 prior to the singulation process for singulating the package module 120. In particular, after forming the backside metal layer 400 on intermediate structure in FIG. 2H, the TIM layer 170 may be formed on the package module 120. The adhesive layer 160 may then be formed on the package module 120 and the package lid 130 may be clamped onto to the package module 120 and the adhesive layer 160. The package lid 130 may be clamped together with package module 120 for a period to allow the adhesive layer 160 to cure and form a secure bond between the package lid 130 and the package module 120. The clamping may be performed, for example, by using a heat clamp module. The heat clamp module may apply a uniform force across the upper surface of the package lid 130.

After the adhesive layer 160 has cured, the intermediate structure may be inverted and the package substrate 110 may be positioned over the intermediate structure so that the package substrate upper bonding pads 114a are over the C4 bumps 121. The package substrate 110 may then be lowered onto the C4 bumps 121 and a reflow process may then be performed to cause a reflow of the solder in the C4 bumps 121.

After the reflow process is complete, the lower molding material layer 327 may be dispensed as a liquid molding material onto the interposer RDL portion 10. The liquid molding material may flow around the C4 bumps 121 and between the interposer RDL portion 10 and the package substrate 110. The liquid molding material may then be cured and hardened to form the lower molding material layer 327. A singulation process may then be performed to singulate the package module 120 with the attached package lid 130 and package substrate 110.

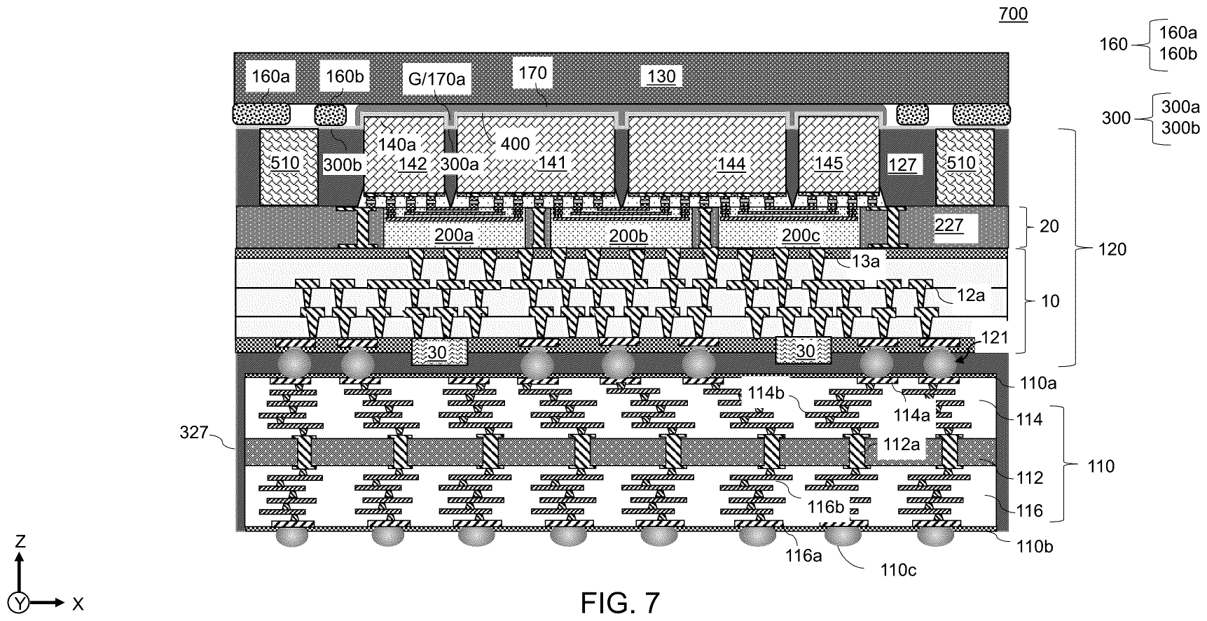

FIG. 7 is a vertical cross-sectional view of the package structure 700 having a first alternative design according to one or more embodiments. The first alternative design is substantially the same as the original design in FIG. 6, and may be formed in a manner similar to the manner of forming the original design. However, in the first alternative design, the package structure 700 may include the first alternative design of the package module 120 in FIG. 4. That is, the package module 120 in the first alternative design of the package structure 700 may include one or more dummy dies 510 in the upper molding material layer 127.

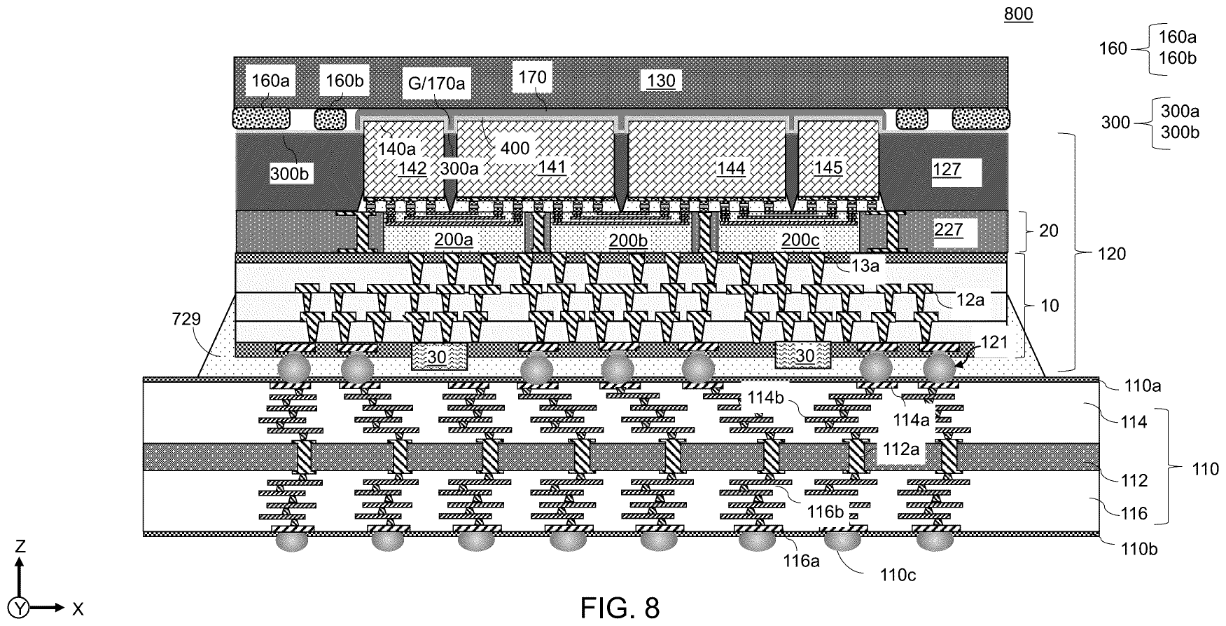

FIG. 8 is a vertical cross-sectional view of the package structure 800 having a second alternative design according to one or more embodiments. The second alternative design may be substantially similar to the original design in FIG. 6. However, the second alternative design may differ from the original design in FIG. 6 in at least the size of the package substrate 110 and the manner in which the package module 120 is bonded to the package substrate 110.

As illustrated in FIG. 8, the package substrate 110 may have a length in the x-direction that is greater than the length of the interposer RDL portion 10 in the x-direction. In at least one embodiment, the length of the package substrate 110 may be at least 10% greater than the length of the interposer RDL portion 10. The package substrate 110 may have a width in the y-direction that is greater (e.g., at least 10% greater) than the width of the interposer RDL portion 10 in the y-direction.

The package module 120 may be bonded to the package substrate 110 by a package underfill layer 729. The package underfill layer 729 may be substantially similar to the package module underfill layer 129 in the package module 120. The package underfill layer 729 may be formed under the interposer RDL portion 10 and around the C4 bumps 121. The package underfill layer 729 may also be formed on the sidewall of the interposer RDL portion 10.

A molding material layer (not shown) (similar to the upper molding material layer 127) may optionally formed over the package underfill layer 729 to provide additional stability to the package structure 800. In that case, the package underfill layer 729 may have a smaller footprint on the package substrate 110 (e.g., in a plan view) than the footprint illustrated in FIG. 8. In particular, the package underfill layer 729 may include an outermost sidewall that is substantially aligned with the outer sidewall of the interposer RDL portion 10, and the molding material layer may be formed on the outermost sidewall of the package underfill layer 729.

The manner of forming the second alternative design in FIG. 8 may be different than the manner of forming the original design in FIG. 6. In the second alterative design, after the singulation process for performed for singulating the package module 120, the package module 120 may be mounted on the package substrate 110. In particular, the package module 120 may be positioned over the package substrate 110 so that the C4 bumps 121 are over the package substrate upper bonding pads 114a. The C4 bumps 121 may then be lowered onto the package substrate upper bonding pads 114a and a reflow process may then be performed to cause a reflow of the solder in the C4 bumps 121.

The package underfill layer 729 may then be applied by depositing and/or injecting an epoxy-based polymeric material onto the package substrate. The epoxy-based polymeric material may be applied on the package substrate 110 and spread (e.g., by capillary action) under the interposer RDL portion 10 and around the C4 bumps 121. In at least one embodiment, the epoxy-based polymeric material may fill substantially all of the gaps between the interposer RDL portion 10 and the package substrate 110. The epoxy-based polymeric material may then be cured, for example, in a box oven for about 90 minutes at about 150° C. to provide the package underfill layer 729 with a sufficient stiffness and mechanical strength.

After the package underfill layer 729 has cured, the TIM layer 170 may be formed on the package module 120. The adhesive layer 160 may then be formed on the package module 120 and the package lid 130 may be clamped onto to the package module 120 and the adhesive layer 160. The package lid 130 may be clamped together with package module 120 and the package substrate 110 for a period to allow the adhesive layer 160 to cure and form a secure bond between the package lid 130 and the package module 120. The clamping may be performed, for example, by using a heat clamp module. The heat clamp module may apply a uniform force across the upper surface of the package lid 130.

After the adhesive layer 160 has adequately cured, the intermediate structure may be inverted and the solder balls 110c of the BGA may be formed on the board-side surface of the package substrate 110. The forming of the solder balls 110c may complete the formation of the second alternative design of the package structure 600.

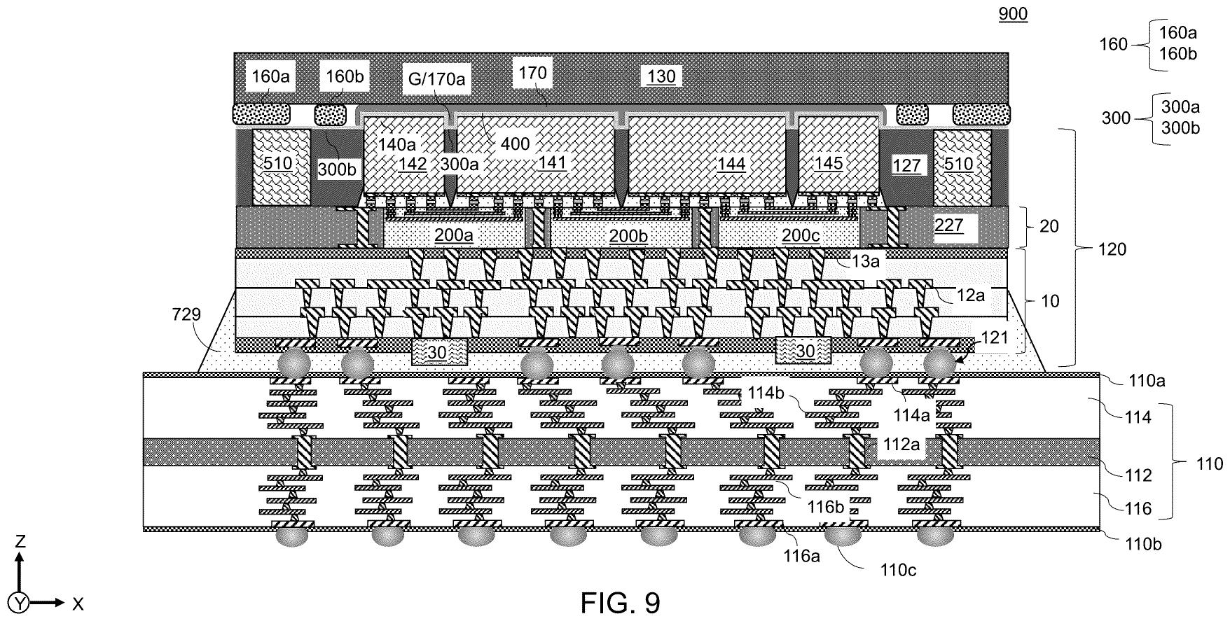

FIG. 9 is a vertical cross-sectional view of the package structure 900 having a third alternative design according to one or more embodiments. The third alternative design may be substantially the same as the second alternative design in FIG. 8, and may be formed in a manner similar to the manner of forming the second alternative design. However, in the third alternative design, the package structure 900 may include the first alternative design of the package module 120 in FIG. 4. That is, the package module 120 in the third alternative design of the package structure 900 may include one or more dummy dies 510 in the upper molding material layer 127.

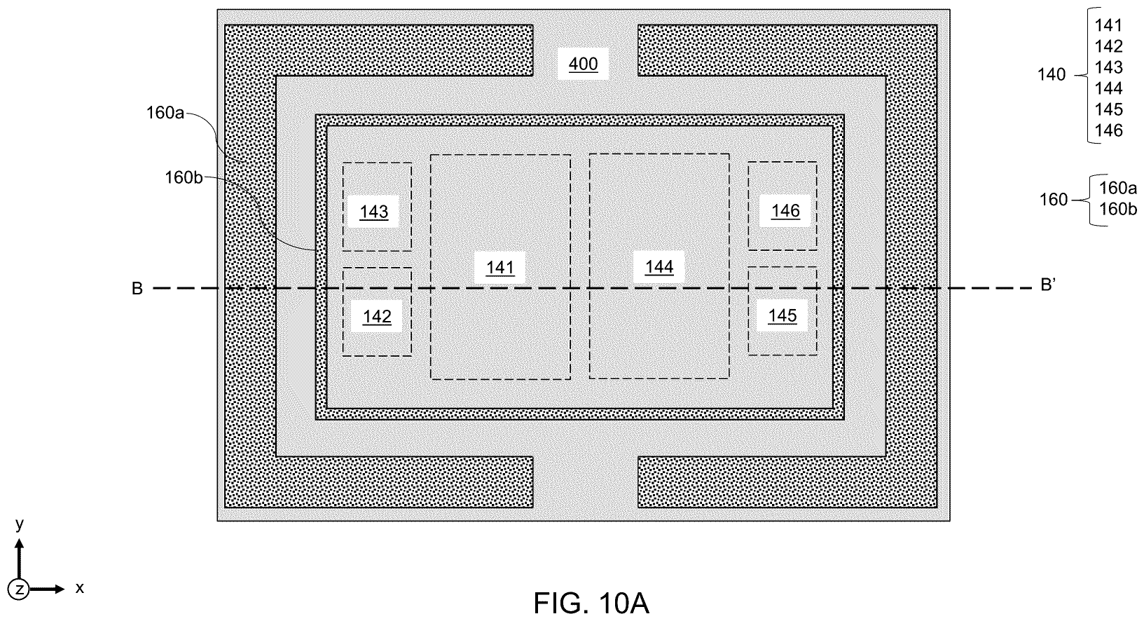

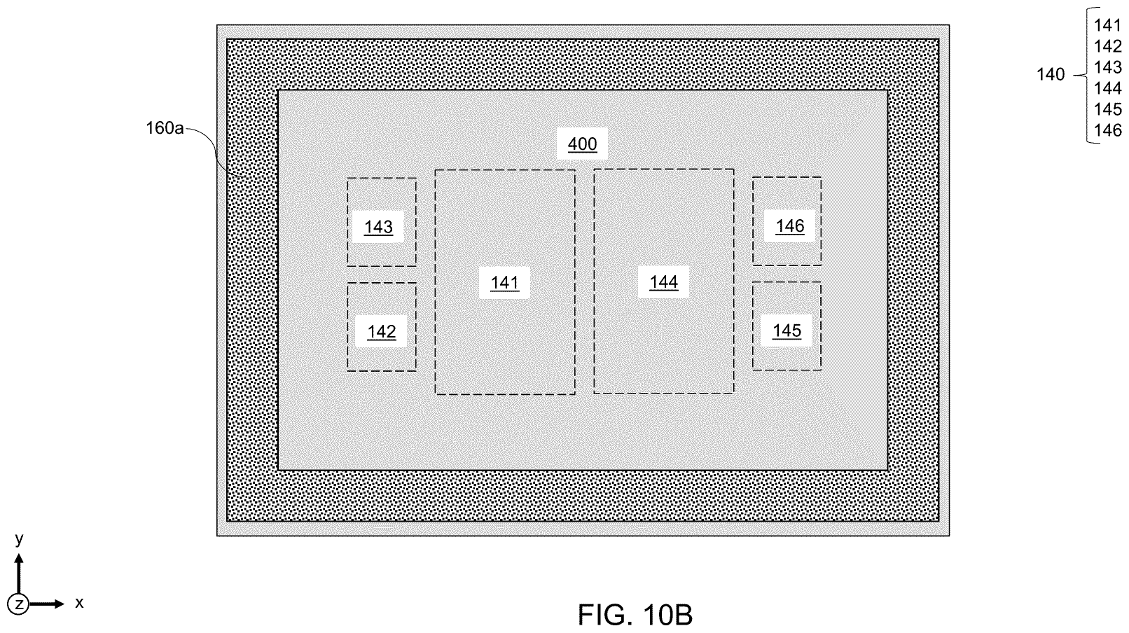

FIGS. 10A-10B are possible design patterns of the adhesive layer 160 in the package structure 600, 700, 800, 900 according to one or more embodiments. The design patterns in FIGS. 10A-10B may be included in the original design of the package structure 600 in FIG. 6, the first alternative structure 700 design in FIG. 7, the second alternative structure 800 design in FIG. 8 and the third alternative structure 900 design in FIG. 9. Generally, the adhesive foot portion 160a and/or the adhesive wall portion 160b may have a frame shape or partial frame shape.

FIG. 10A is a plan view of the adhesive layer 160 having a first design pattern according to one or more embodiments. The vertical cross-sectional view in FIGS. 6-9 is along the line B-B′ in FIG. 10A. As illustrated in FIG. 10A, the adhesive foot portion 160a may have a partial frame shape. In particular, the adhesive foot portion 160a may not be formed continuously around the entire periphery of the semiconductor dies 140. Instead, the adhesive foot portion 160a may be discontinued at one or more locations around the periphery of the semiconductor dies 140. The adhesive foot portion 160a may be formed as two or more separate beads of adhesive material around the periphery of the adhesive wall portion 160b. In at least one embodiment (illustrated in FIG. 10A), the adhesive foot portion 160a may be formed as two U-shaped sections that are separated near a central portion of the package structure 600, 700, 800, 900. The two U-shaped sections may have a substantially similar size and shape.

A width of the adhesive foot portion 160a may be substantially uniform over the entirety of the adhesive wall portion 160a. The width of the adhesive foot portion 160a may be greater than the width of the adhesive wall portion 160b. In at least one embodiment, the width of the adhesive foot portion 160a may be at least 50% greater than the width of the adhesive wall portion 160b.

In contrast, the adhesive wall portion 160b in the first design pattern may have a frame shape. In particular, the adhesive wall portion 160b may be formed as a continuous bead of adhesive material around an outer periphery of the semiconductor dies 140. A width of the adhesive wall portion 160b may be substantially uniform over the entirety of the adhesive wall portion 160b. The adhesive layer 160 in the first design pattern may be formed and patterned, for example, by any suitable dispensing technique.

FIG. 10B is a plan view of the adhesive layer 160 having a second design pattern according to one or more embodiments. As illustrated in FIG. 10B, the adhesive wall portion 160b of FIG. 10A may be omitted from the second design pattern. That is, the adhesive layer 160 may be constituted by the adhesive foot portion 160a. The adhesive foot portion 160a may be formed as a continuous bead of adhesive material around an outer periphery of the semiconductor dies 140. A width of the adhesive foot portion 160a may be substantially uniform over the entire periphery of the semiconductor dies 140. The adhesive layer 160 in the second design pattern may also be formed and patterned, for example, by any suitable dispensing technique.

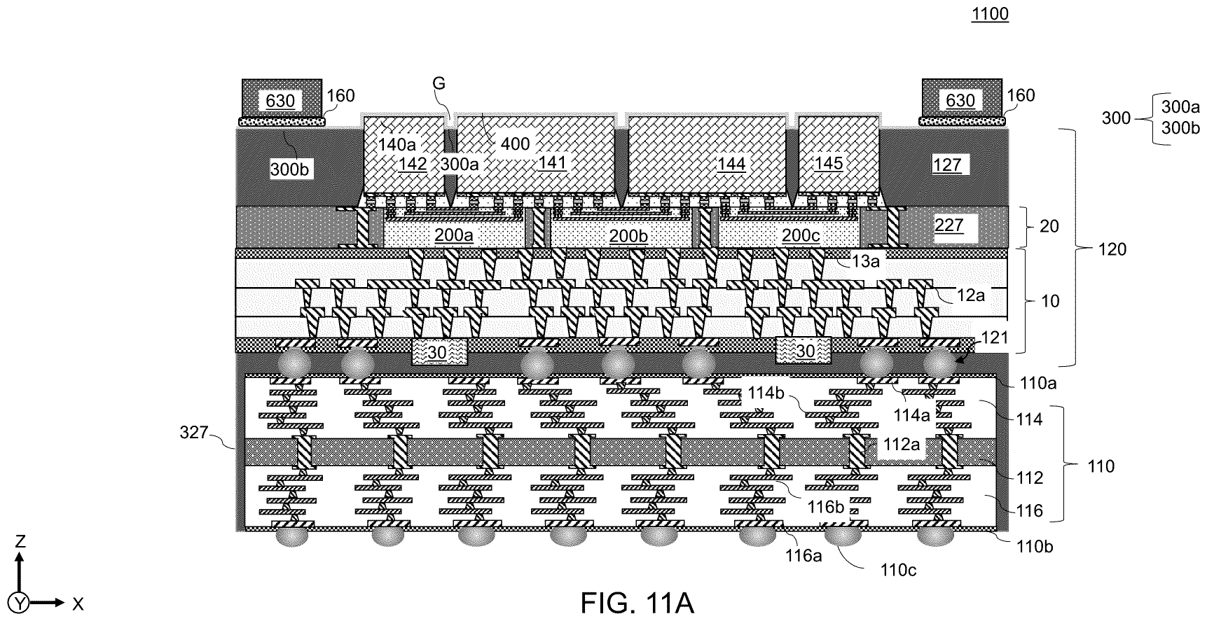

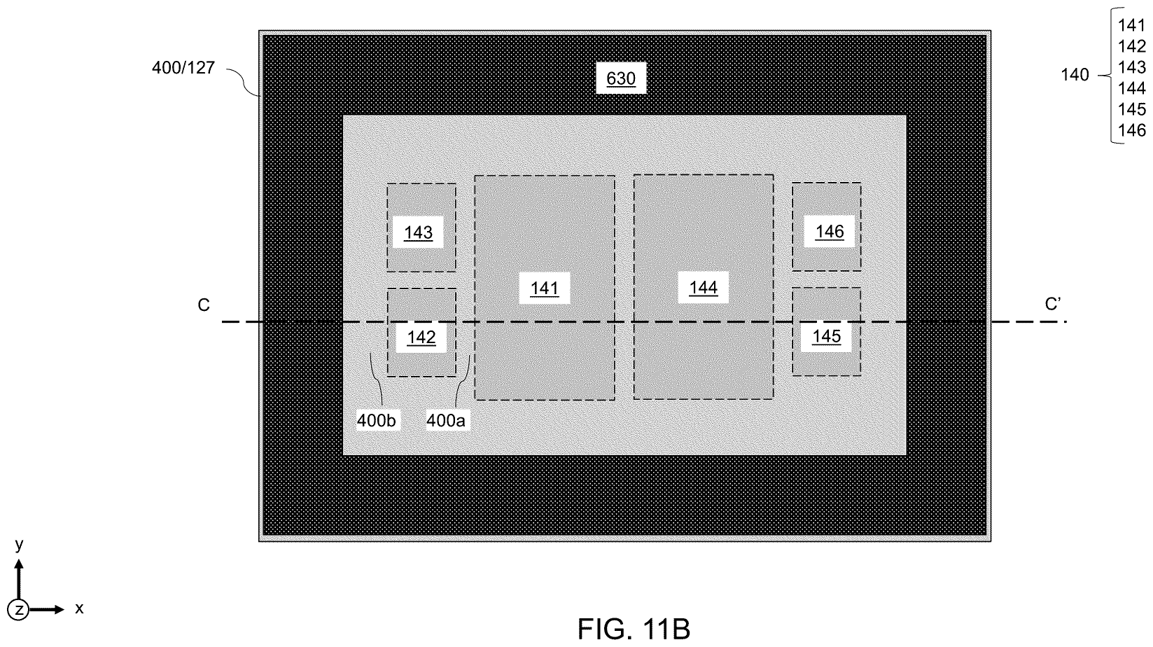

FIGS. 11A-14 are vertical cross-sectional views of the package structure 600 having alternative designs according to one or more embodiments. In particular, FIG. 11A is a vertical cross-sectional view of a package structure 600 having a fourth alternative design according to one or more embodiments. FIG. 11B is a plan view (i.e., top-down view) of the package structure 1100 having the fourth alternative design according to one or more embodiments. The vertical cross-sectional view in FIG. 11A is along the line C-C′ in FIG. 11B.

As illustrated in FIG. 11A, the package structure 1100 having the fourth alternative design may be substantially similar to the package structure 600 in FIG. 6. In particular, the fourth alternative design may include the package substrate 110 and the package module 120 on the package substrate 110.

However, in the fourth alternative design in FIG. 11A, the package structure 1100 may not include the TIM layer 170 and may not include the package lid 130. Instead, in the fourth alternative design, the package structure 1100 may include a stiffener ring 630 on the package module 120. The stiffener ring 630 may be formed of a material similar to the material of the package lid 130. The stiffener ring 630 may be attached to the package module 120 by the adhesive layer 160. In particular, the stiffener ring 630 may be attached through the adhesive layer 160 to the backside metal layer 400 over the outer recessed surface portion 300b of the upper molding material layer 127. The stiffener ring 630 may be attached in a manner similar to the manner of attaching the package lid 130 described above with respect to FIG. 6.

Although not illustrated in FIG. 11A, in at least one embodiment, the backside metal layer 400 may not be formed on at least a portion of the outer recessed surface portion 300b of the upper molding material layer 127. In that embodiment, at least a portion of the stiffener ring 630 may be attached directly to the outer recessed surface portion 300b of the upper molding material layer 127. Further, although not illustrated in FIG. 11A, in at least one embodiment, the stiffener ring 630 may be attached through the adhesive layer 160 to the molding material layer 227 (e.g., encapsulation layer) of the interposer molded portion 20. In that embodiment, the stiffener ring 630 may be embedded in the upper molded material layer 127.

As illustrated in FIG. 111B, the stiffener ring 630 may be continuously formed around an entire periphery of the semiconductor dies 140. The backside metal layer 400 may be cover an entirety of the upper molding material layer 127 and the semiconductor dies 140. The stiffener ring 630 may have a shape that is substantially similar to an outer shape of the upper molding material layer 127 (e.g., an outer shape of the package module 120) and an outer shape of the backside metal layer 400. In particular, the stiffener ring 630 may have a substantially rectangular outer shape and a substantially rectangular inner shape. Other suitable shapes of the stiffener ring 630 may be used. In at least one embodiment, a distance between an inner wall of the stiffener ring 630 and the semiconductor dies 140 may be greater than a distance between an outer wall of the stiffener ring 630 and an outermost edge of the package module 120 (e.g., outer most edge of the backside metal layer 400).

A width of the stiffener ring 630 may be substantially uniform around the entire periphery of the semiconductor dies 140. In at least one embodiment, the width of the stiffener ring 630 may be greater than the distance between the inner wall of the stiffener ring and the semiconductor dies 140. In at least one embodiment, the width of the stiffener ring 630 may be in a range from 20% to 90% of a distance between the semiconductor dies 140 and the outermost edge of the package module 120 (e.g., outer most edge of the backside metal layer 400).

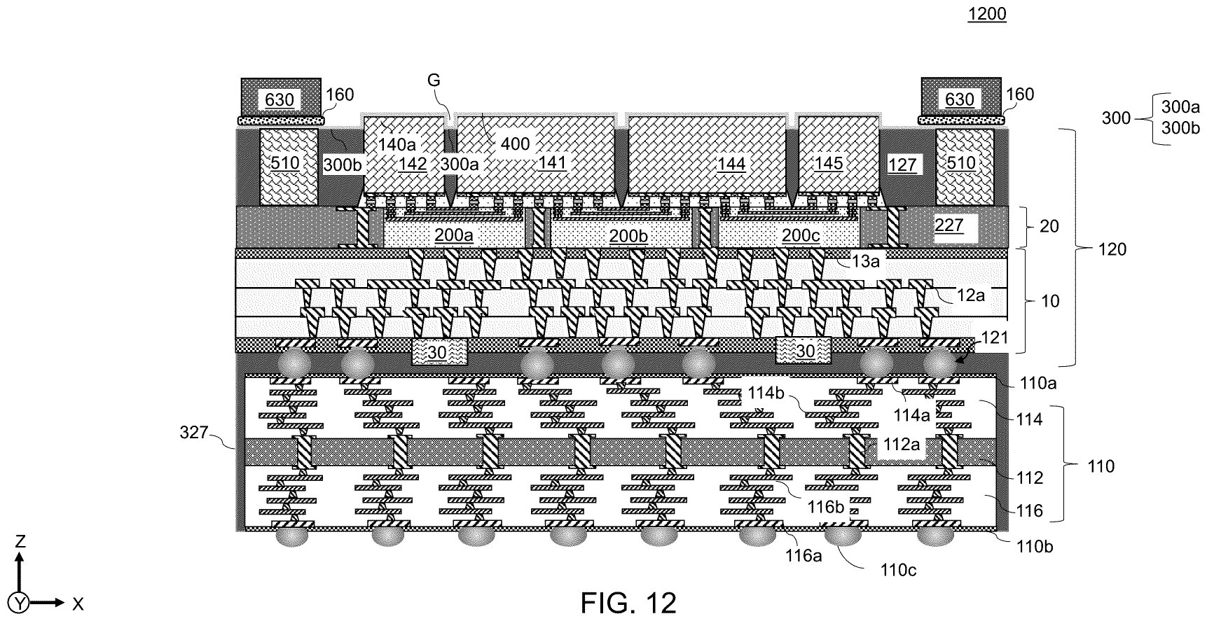

FIG. 12 is a vertical cross-sectional view of a package structure 1200 having a fifth alternative design according to one or more embodiments. The plan view (i.e., top-down view) of the package structure 1200 having the fifth alternative design may be substantially the same as the plan view of the package structure 1100 having the fourth alternative design in FIG. 11B.

As illustrated in FIG. 12, the package structure 1200 having the fifth alternative design may be substantially similar to the package structure 700 having the first alternative design in FIG. 7. In particular, in the fifth alternative design the package structure 1200 may include one or more dummy dies 510 in the upper molding material layer 127. However, in the fifth alternative design in FIG. 12, the package structure 1200 may not include the TIM layer 170 and may not include the package lid 130. Instead, in the fifth alternative design, the package structure 1200 may include the stiffener ring 630 on the package module 120. The material, design and location of the stiffener ring 630 in the fifth alternative design may be substantially the same as that in the fourth alternative design of FIGS. 11A-11B. In addition, the stiffener ring 630 may be located over at least a portion of the dummy dies 510.

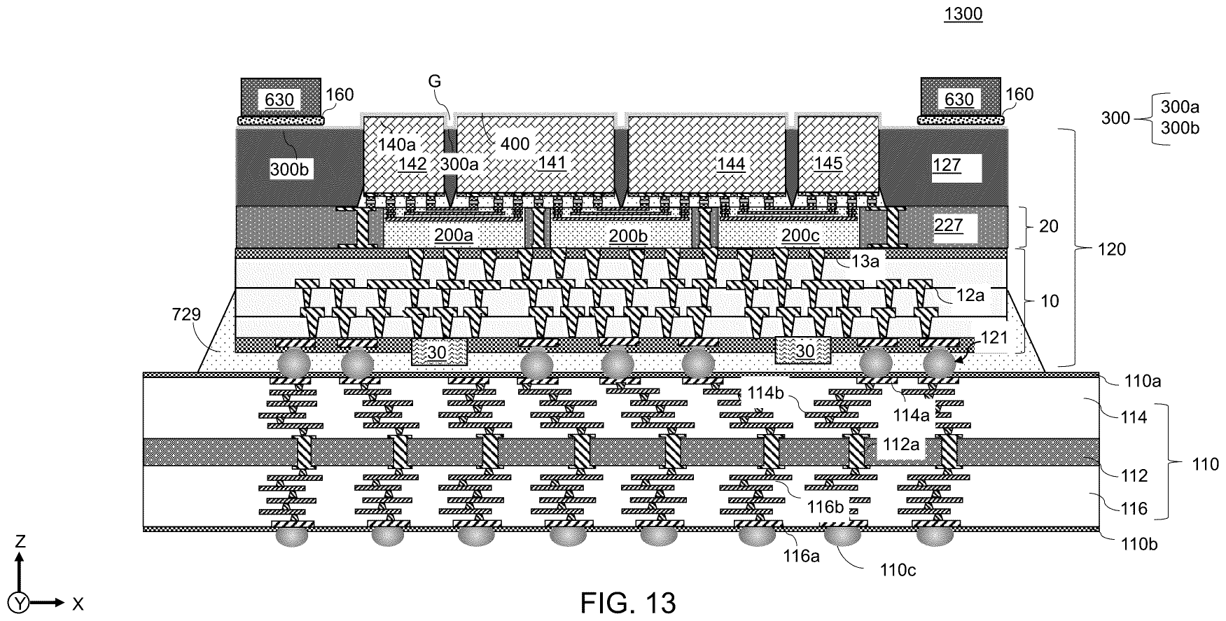

FIG. 13 is a vertical cross-sectional view of a package structure 1300 having a sixth alternative design according to one or more embodiments. The plan view (i.e., top-down view) of the package structure 1300 having the sixth alternative design may be substantially the same as the plan view of the package structure 1100 having the fourth alternative design in FIG. 11B.

As illustrated in FIG. 13, the package structure 1300 having the sixth alternative design may be substantially similar to the package structure 800 having the second alternative design in FIG. 8. Thus, for example, the package substrate 110 may have a length in the x-direction and width in the y-direction that is greater than the length and width of the interposer RDL portion 10, respectively. The package module 120 may be bonded to the package substrate 110 by a package underfill layer 729. A molding material layer (not shown) (similar to the upper molding material layer 127) may optionally formed over the package underfill layer 729 to provide additional stability to the package structure 1300.

However, in contrast to the second alternative design in FIG. 8, in the sixth alternative design in FIG. 13, the package structure 1300 may not include the TIM layer 170 and may not include the package lid 130. Instead, in the sixth alternative design, the package structure 1300 may include the stiffener ring 630 on the package module 120. The material, design and location of the stiffener ring 630 in the sixth alternative design may be substantially the same as that in the fourth alternative design of FIGS. 11A-11B.

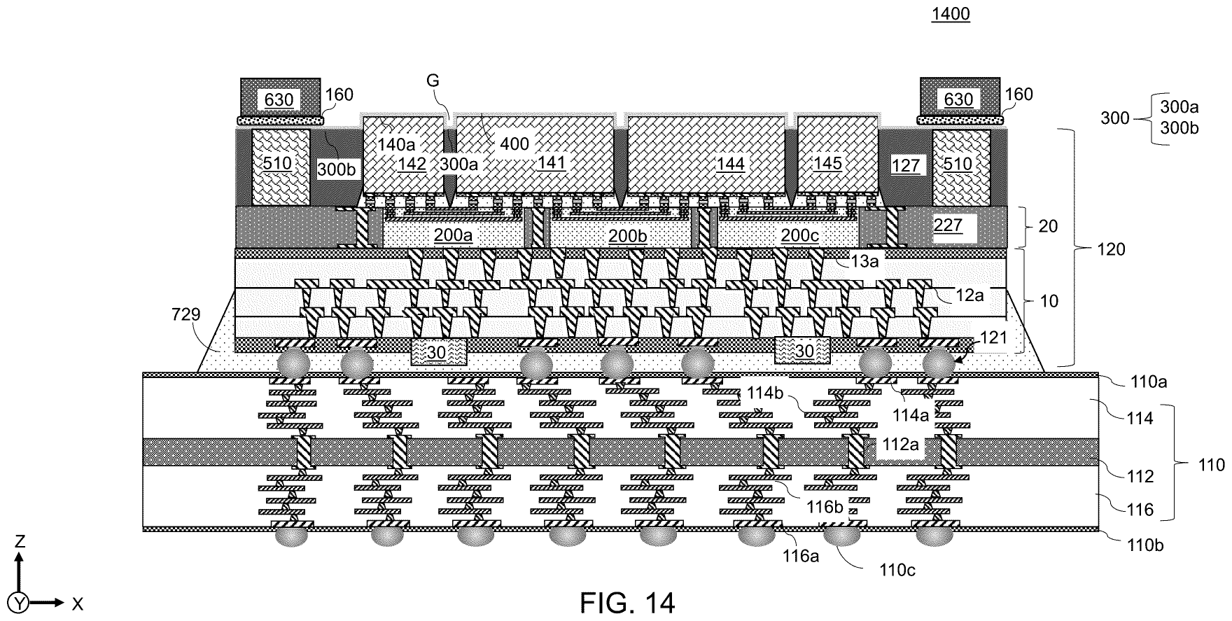

FIG. 14 is a vertical cross-sectional view of a package structure 1400 having a seventh alternative design according to one or more embodiments. The plan view (i.e., top-down view) of the package structure 1400 having the seventh alternative design may be substantially the same as the plan view of the package structure 1100 having the fourth alternative design in FIG. 11B.

As illustrated in FIG. 14, the package structure 1400 having the seventh alternative design may be substantially similar to the package structure 900 having the third alternative design in FIG. 9. In particular, in the seventh alternative design the package structure 1400 may include one or more dummy dies 510 in the upper molding material layer 127. However, in the seventh alternative design in FIG. 14, the package structure 1400 may not include the TIM layer 170 and may not include the package lid 130. Instead, in the seventh alternative design, the package structure 1400 may include the stiffener ring 630 on the package module 120. The material, design and location of the stiffener ring 630 in the seventh alternative design may be substantially the same as that in the fourth alternative design of FIGS. 11A-11B. In addition, the stiffener ring 630 may be located over at least a portion of the dummy dies 510.

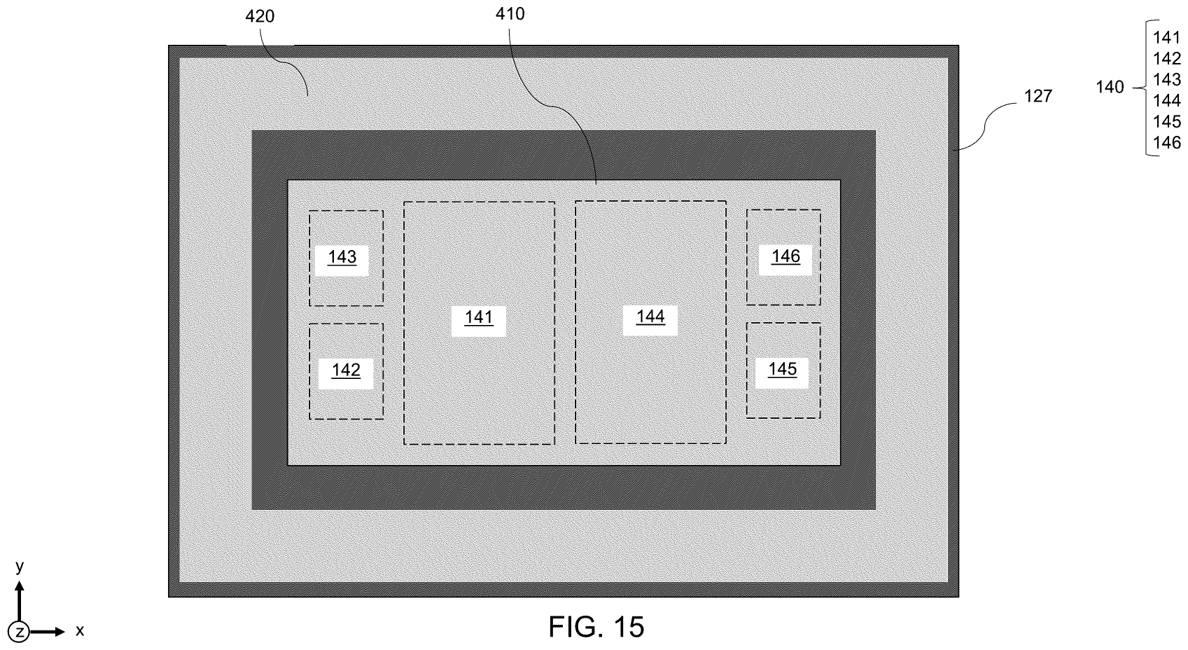

FIG. 15 is a plan view of a third alternative design of the backside metal layer 400 according to one or more embodiments. In FIG. 15, shading and dashed lines are used to indicate a location of the semiconductor dies 140 that may be located underneath the backside metal layer 400.

The third alternative design of the backside metal layer 400 may be included in the package structure 1100, 1200, 1300, 1400 including the stiffener ring 630 in FIGS. 11A-14, in addition to the package structure 600, 700, 800, 900 including the package lid 130 in FIGS. 6-9. The third alternative design of the backside metal layer 400 may be substantially similar to the second alternative design in FIG. 5B. That is, the backside metal layer 400 may include the central portion 410 and the peripheral portion 420. However, in contrast to the second alternative design in FIG. 5B, in the third alternative design, the peripheral portion 420 may have a complete frame shape that is formed continuously around the central portion 410.

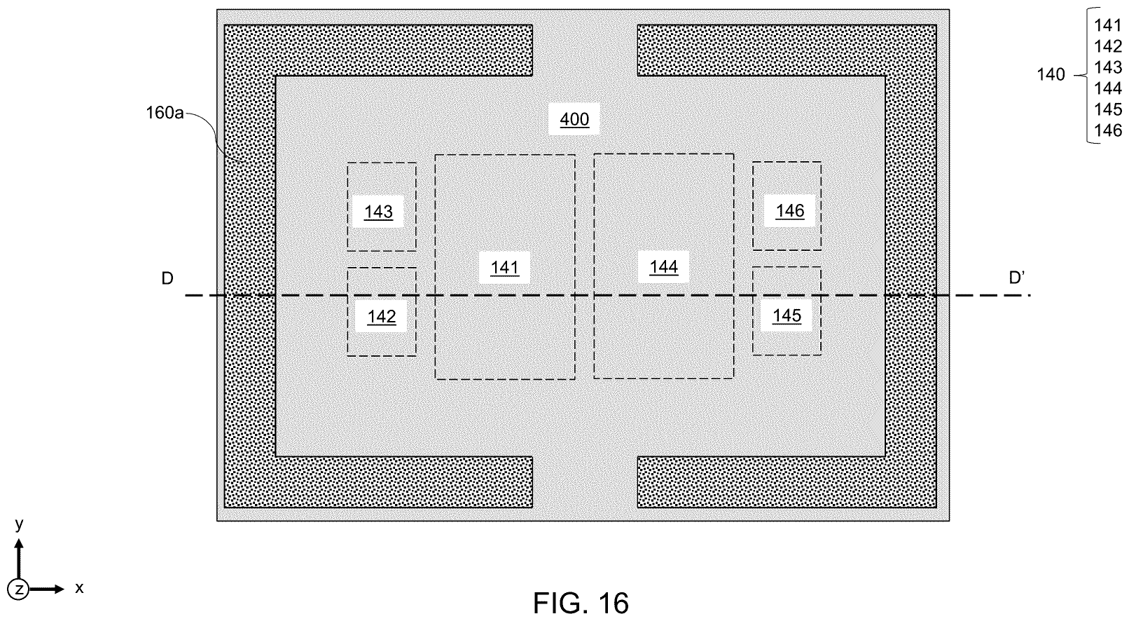

FIG. 16 is a plan view of the adhesive layer 160 having a third design pattern according to one or more embodiments. The vertical cross-sectional view in FIGS. 11A and 12-14 is along the line D-D′ in FIG. 16. The third alternative design of the backside metal layer 400 may be included in the package structure 600 including the stiffener ring 630 in FIGS. 11A-14, in addition to the package structure 600 including the package lid 130 in FIGS. 6-9.

As illustrated in FIG. 16, the third design pattern of the adhesive layer 160 may be substantially similar to the second design pattern in FIG. 10B. That is, the adhesive layer 160 may be constituted by the adhesive foot portion 160a. However, in contrast to the second design pattern in FIG. 10B, in the third design pattern, the adhesive foot portion 160a may have a frame shape. A location and width of the adhesive foot portion 160a may substantially correspond to the location and width of the stiffener ring 630 in FIGS. 11A-14. The adhesive foot portion 160a may be formed continuously around the entire periphery of the semiconductor dies 140. In particular, the adhesive foot portion 160a may be formed as a continuous bead of adhesive material around an outer periphery of the semiconductor dies 140. A width of the adhesive foot portion 160a may be substantially uniform over the entirety of the adhesive foot portion 160a. The adhesive foot portion 160a in the third design pattern may be formed and patterned, for example, by any suitable dispensing technique.

Referring now to FIGS. 1A-16, a package module 120 may include an interposer 5, a plurality of semiconductor dies 140 on the interposer 5 and including a semiconductor die upper surface 140a, an upper molding material layer 127 on the plurality of semiconductor dies 140 and including a recessed upper surface 300 that may be recessed from the semiconductor die upper surface 140a, and a backside metal layer 400 on the recessed upper surface 300 of the upper molding material layer 127.

In one embodiment, the recessed upper surface 300 of the upper molding material layer 127 may include an inner recessed surface portion 300a between the plurality of semiconductor dies 140, and the backside metal layer 400 may include an inner backside metal layer portion 400a on the inner recessed surface portion 300a. In one embodiment, the recessed upper surface 300 of the upper molding material layer 127 may further include an outer recessed surface portion 300b outside the plurality of semiconductor dies 140, and the backside metal layer 400 may include an outer backside metal layer portion 400b on the outer recessed surface portion 300b. In one embodiment, the recessed upper surface 300 of the upper molding material layer 127 may include an entire upper surface of the upper molding material layer 127, and the backside metal layer 400 may be on the entire upper surface of the upper molding material layer 127. In one embodiment, the backside metal layer 400 may be on the semiconductor die upper surface 140a of the plurality of semiconductor dies 140. In one embodiment, the backside metal layer 400 may be formed continuously between the semiconductor die upper surface 140a, a sidewall of the plurality of semiconductor dies 140, and the recessed upper surface 300 of the upper molding material layer 127. In one embodiment, the interposer 5 may include an interposer redistribution layer (RDL) portion 10, and an interposer molded portion 20 on the interposer RDL portion 10, wherein the interposer molded portion 20 may include a local silicon interconnect (LSI) die 200a, 200b, 200c interconnecting the plurality of semiconductor dies 140. In one embodiment, the package module 120 may further include a dummy die 510 on the interposer molded portion 20 and in the upper molding material layer 127. In one embodiment, a depth of the recessed upper surface 300 from the semiconductor die upper surface 140a may be less than 10 μm.

Referring again to FIGS. 1A-16, a package structure 600 may include a package substrate 110 and a package module 120 on the package substrate 110. The package module 120 may include an interposer 5, a plurality of semiconductor dies 140 on the interposer 5 and including a semiconductor die upper surface 140a, an upper molding material layer 127 on the plurality of semiconductor dies 140 and including a recessed upper surface 300 that may be recessed from the semiconductor die upper surface 140a, and a backside metal layer 400 on the recessed upper surface 300 of the upper molding material layer 127.

In one embodiment, the package structure 600 may further include one of a package lid 130 or a stiffener ring 630 on the package module 120. In one embodiment, the package structure 600 may include the package lid 130 and further include a thermal interface material (TIM) layer 170 on the package module 120, wherein the package lid 130 may be on the TIM layer 170. In one embodiment, the recessed upper surface 300 of the upper molding material layer 127 may include an inner recessed surface portion 300a between the plurality of semiconductor dies 140, the backside metal layer 400 may include an inner backside metal layer portion 400a on the inner recessed surface portion 300a, and the TIM layer 170 may include a TIM layer 170 projecting portion projecting onto the inner backside metal layer portion 400a. In one embodiment, the package structure 600 may further include an adhesive layer 160 connecting the package lid 130 to the package module 120, wherein the adhesive layer 160 contacts at least one of the backside metal layer 400 or the recessed upper surface 300 of the upper molding material layer 127. In one embodiment, the adhesive layer 160 may include an adhesive foot portion 160a at a sidewall of the package module 120 and an adhesive wall portion 160b between the adhesive foot portion 160a and the plurality of semiconductor dies 140. A thickness of the adhesive layer 160 may be in a range from 50 μm to 200 μm.

Referring again to FIGS. 1A-16, a method of forming a package module 120 may include forming an interposer 5, mounting a plurality of semiconductor dies 140 on the interposer 5, wherein the plurality of semiconductor dies 140 include a semiconductor die upper surface 140a, forming an upper molding material layer 127 on the plurality of semiconductor dies 140 such that the upper molding material layer 127 includes a recessed upper surface 300 that may be recessed from the semiconductor die upper surface 140a, and forming a backside metal layer 400 on the recessed upper surface 300 of the upper molding material layer 127.

In one embodiment, the forming of the upper molding material layer 127 may include forming the recessed upper surface 300 of the upper molding material layer 127 to include an inner recessed surface portion 300a between the plurality of semiconductor dies 140, and the forming of the backside metal layer 400 may include forming the backside metal layer 400 to include an inner backside metal layer portion 400a on the inner recessed surface portion 300a. In one embodiment, the forming of the upper molding material layer 127 may include forming the recessed upper surface 300 of the upper molding material layer 127 to include an outer recessed surface portion 300b outside the plurality of semiconductor dies 140, and the backside metal layer 400 may include an outer backside metal layer portion 400b on the outer recessed surface portion 300b. In one embodiment, the forming of the backside metal layer 400 may include forming the backside metal layer 400 on the semiconductor die upper surface 140a of the plurality of semiconductor dies 140. In one embodiment, the forming of the interposer 5 may further include forming an interposer redistribution layer (RDL) portion 10 on a carrier substrate 1 and forming an interposer molded portion 20 on the interposer RDL portion 10, wherein the interposer molded portion 20 may include a local silicon interconnect (LSI) die 200a, 200b, 200c interconnecting the plurality of semiconductor dies 140.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package module, comprising:
an interposer;
a plurality of semiconductor dies on the interposer and including a semiconductor die upper surface;
an upper molding material layer on the plurality of semiconductor dies and including a recessed upper surface that is recessed from the semiconductor die upper surface; and
a backside metal layer on the recessed upper surface of the upper molding material layer.

2. The package module of claim 1, wherein the recessed upper surface of the upper molding material layer includes an inner recessed surface portion between the plurality of semiconductor dies, and the backside metal layer comprises an inner backside metal layer portion on the inner recessed surface portion.

3. The package module of claim 2, wherein the recessed upper surface of the upper molding material layer further includes an outer recessed surface portion outside the plurality of semiconductor dies, and the backside metal layer comprises an outer backside metal layer portion on the outer recessed surface portion.

4. The package module of claim 1, wherein the recessed upper surface of the upper molding material layer comprises an entire upper surface of the upper molding material layer, and the backside metal layer is on the entire upper surface of the upper molding material layer.

5. The package module of claim 1, wherein the backside metal layer is on the semiconductor die upper surface of the plurality of semiconductor dies.

6. The package module of claim 1, wherein the backside metal layer is formed continuously between the semiconductor die upper surface, a side surface of the plurality of semiconductor dies, and the recessed upper surface of the upper molding material layer.

7. The package module of claim 1, wherein the interposer comprises:
an interposer redistribution layer (RDL) portion; and
an interposer molded portion on the interposer RDL portion, wherein the interposer molded portion comprises a local silicon interconnect (LSI) die interconnecting the plurality of semiconductor dies.

8. The package module of claim 7, further comprising:
a dummy die on the interposer molded portion and in the upper molding material layer.

9. The package module of claim 1, wherein a depth of the recessed upper surface from the semiconductor die upper surface is less than 10 μm.

10. A package structure, comprising:
a package substrate;
a package module on the package substrate, comprising:
an interposer;
a plurality of semiconductor dies on the interposer and including a semiconductor die upper surface;
an upper molding material layer on the plurality of semiconductor dies and including a recessed upper surface that is recessed from the semiconductor die upper surface; and
a backside metal layer on the recessed upper surface of the upper molding material layer; and
one of a package lid or a stiffener ring on the package module.

11. The package structure of claim 10, wherein the package structure includes the package lid, and the package structure further comprises:
a thermal interface material (TIM) layer on the package module, wherein the package lid is on the TIM layer.

12. The package structure of claim 11, wherein the recessed upper surface of the upper molding material layer comprises an inner recessed surface portion between the plurality of semiconductor dies, the backside metal layer comprises an inner backside metal layer portion on the inner recessed surface portion, and the TIM layer comprises a TIM layer projecting portion projecting onto the inner backside metal layer portion.

13. The package structure of claim 11, further comprising:
an adhesive layer connecting the package lid to the package module, wherein the adhesive layer contacts at least one of the backside metal layer or the recessed upper surface of the upper molding material layer.

14. The package structure of claim 13, wherein the adhesive layer comprises an adhesive foot portion at a sidewall of the package module and an adhesive wall portion between the adhesive foot portion and the plurality of semiconductor dies.

15. The package structure of claim 13, wherein a thickness of the adhesive layer is in a range from 50 μm to 200 μm.

16. A method of forming a package module, the method comprising:
forming an interposer;
mounting a plurality of semiconductor dies on the interposer, wherein the plurality of semiconductor dies include a semiconductor die upper surface;
forming an upper molding material layer on the plurality of semiconductor dies such that the upper molding material layer includes a recessed upper surface that is recessed from the semiconductor die upper surface; and
forming a backside metal layer on the recessed upper surface of the upper molding material layer.

17. The method of claim 16, wherein the forming of the upper molding material layer comprises forming the recessed upper surface of the upper molding material layer to include an inner recessed surface portion between the plurality of semiconductor dies, and the forming of the backside metal layer comprises forming the backside metal layer to include an inner backside metal layer portion on the inner recessed surface portion.

18. The method of claim 16, wherein the forming of the upper molding material layer comprises forming the recessed upper surface of the upper molding material layer to include an outer recessed surface portion outside the plurality of semiconductor dies, and the backside metal layer comprises an outer backside metal layer portion on the outer recessed surface portion.

19. The method of claim 16, wherein the forming of the backside metal layer comprises forming the backside metal layer on the semiconductor die upper surface of the plurality of semiconductor dies.

20. The method of claim 16, wherein the forming of the interposer comprises:
forming an interposer redistribution layer (RDL) portion on a carrier substrate; and
forming an interposer molded portion on the interposer RDL portion, wherein the interposer molded portion comprises a local silicon interconnect (LSI) die interconnecting the plurality of semiconductor dies.
